(19) United States
(12) Patent Application Publication
(10) Pub. No.: US 2008/0199814 A1
(43) Pub. Date: Aug. 21, 2008

(54) Device manufacturing process utilizing a double patterning process

(75) Inventors: Dave Brzozowy, Bristol, RI (US); Thomas R. Sarubbi, East Greenwich, RI (US); Sanjay Malik, Attleboro, MA (US); Gregory Spaziano, Cranston, RI (US)

Correspondence Address: Paul D. Greeley, Esq.;Ohlandt, Greeley, Ruggiero & Perle, L.L.P., 10th Floor, One Landmark Square, Stamford, CT, 06901-2682, US

(73) Assignee: FUJIFILM ELECTRONIC MATERIALS, U.S.A., INC.

(21) Appl. No.: 11/999,104

(22) Filed: Dec. 4, 2007

Related U.S. Application Data
(60) Provisional application No. 60/873,117, filed on Dec. 6, 2006.
(60) Provisional application No. 60/902,213, filed on Feb. 20, 2007.

(51) Int. Cl. H01L 21/00

(52) U.S. Cl. 430/312

(57) ABSTRACT

Manufacturing semiconductor device by steps of:
a) providing substrate with antireflective coating or underlayer,
b) applying first photosensitive composition over substrate,
c) exposing first composition to radiation to produce first pattern,
d) developing exposed first composition to produce an imaged bilayer stack,
e) rinsing the stack,
f) applying fixer to the stack,
g) applying optional bake,
h) rinsing the stack,
i) applying second optional bake,
j) applying second photosensitive composition onto the stack to produce multilayer stack,
k) exposing second composition to produce second pattern offset from first pattern,
l) developing exposed second composition to produce multilayer stack, and
m) rinsing multilayer stack;
   the photosensitive compositions have photoacid generator and substantially aqueous base insoluble polymer whose solubility increases upon treatment with acid and further comprises an anchor group, and the fixer is a polyfunctional compound reactive with anchor group, but does not contain silicon and the substrate stays within a lithographic cell from at least first coating step until at least after final exposure.

### RELATED APPLICATIONS

This application claims priority of U.S. Provisional Patent Application No. 60/873,117, filed Dec. 6, 2006 and U.S. Provisional Patent Application No. 60/902,213, filed Feb. 20, 2007.

### FIELD OF THE INVENTION

The present invention relates to a process of manufacturing a semiconductor device. More specifically, the present invention relates to a multiple exposure patterning process to manufacture relief images used in manufacture of a semiconductor device wherein the semiconductor substrate stays within a lithographic cell from the first coating step until at least after the final exposure.

### BACKGROUND TO THE INVENTION

The trend in the IC industry is to print smaller and smaller critical dimensions (CD's). The critical dimensions within an integrated circuit are defined by a reticle or mask pattern, and an exposure tool which projects the image from the reticle onto a substrate. To achieve the trend toward size reduction for semiconductor devices, the illumination wavelength used within the exposure tool has been decreasing and the numerical aperture (NA) used within the exposure tool has been increasing.

It is generally known that resolution of an imaging system, can be expressed by the following equations:

Resolution=k₁*(lambda/NA)

where lambda is the wavelength of exposing light, and NA is the numerical aperture of the projecting lens; and k₁ is a coefficient related to the process.

One known method to improve resolution is to utilize an exposure source having shorter wavelength. Development efforts are underway to introduce an EUV source having exposure wavelength in the range of 13.5 nm. This method has been slow to reach the market due to the immaturity of photoresist systems, and the source limitations associated with the EUV tool. The desired output of the EUV systems is targeted to be 180 Watts for production applications. The current systems are only capable to producing 20-40 Watts of output power, which impractical for production use. The timing required to resolve the current issues related to this technology will not likely be available for next generation 32 nm node requirements.

A reduction in the k₁ coefficient related to the process, is another known method for improving resolution. The k₁ coefficient for a single exposure process is limited to a value equivalent to approximately 0.25, due to diffraction limitations of printing dense structures.

An alternative approach to lowering the k₁ coefficient has recently been developed which uses a double exposure process. The k₁ coefficient can be decrease to 0.14, which can significantly improve resolution. The double exposure process having a k₁ coefficient of 0.14 was been reported by IMEC at the FUJIFILM Interface 2006 symposium. 32 nm features having a 65 nm pitch, were produced using a litho-etch-litho-etch double exposure process was presented. An overview of this process is provided in FIG. 1 for reference. The technique relies upon first producing a first image pattern with a lower density of features than that of the desired final image. After various steps, a second patterning sequence is carried out to generate a second image pattern of similar low density, which is offset by a specific distance from the first image pattern and has features interspersed within the original pattern features. In combination, the two patterning sequences provide features at the desired density. In order to generate the desired pattern density, very tight control of mask alignment and overlay must be maintained.

The prior art process described above requires, in addition to numerous coating steps and two exposure steps, 2 BARC etches, a hardmask etch, and a substrate etch. The etch steps require the substrate in process to leave the lithography cluster, resulting in higher complexity, more potential for contamination, slower throughput, and higher cost.

A similar double exposure process was also published in Society of Photo-Optical Instrumentation Engineers, 5754, 1513 (2005). The process did not employ the hardmask but required two substrate etch steps.

It is a goal of this invention to provide a high resolution, multiple exposure patterning process that decreases k₁, while keeping the substrate-in-process within the lithography cell from the first coating step until at least after the final exposure. However, several technical problems to this approach exist. Principally, such an approach requires the capability of preparing one or more additional layers of organic material in high quality coatings and lithographically processing them over the initially patterned photoresist without dissolving a significant amount of the initial photoresist or otherwise degrading the high resolution images. In addition, the materials employed in the processes should be compatible with the existing manufacturing waste streams and be able to be used in the contamination-controlled environment of the lithography cluster. The materials and processes to accomplish this are not readily obvious.

U.S. Pat. Nos. 5,173,393, 7,033,740, 6,998,215, 6,899,997, 6,893,972, 6,770,423, 6,703,190, 5,250,375, 7,045,274 and 7,067,234, herein incorporated by reference, describe methods of treating resist images with a chemical solution to alter certain properties of the resist image. However, this technique has not been previously employed in double exposure processes for ultra high resolution imaging.

### SUMMARY OF THE INVENTION

The present invention relates to a multiple exposure patterning process to manufacture relief images used in manufacture of a semiconductor device. The invention is a process for manufacturing a semiconductor device using a multiple exposure patterning process, comprising:
a) providing a coated semiconductor substrate with an antireflective coating or an underlayer,
b) applying in a first coating step, a first photosensitive composition over the coated semiconductor substrate to produce a bilayer stack,
c) exposing the first photosensitive composition in the bilayer stack in a imagewise manner to actinic radiation in a first exposure step to produce a first pattern,
d) developing the exposed first photosensitive composition in an aqueous base developer to produce an imaged bilayer stack containing a relief image,
e) rinsing the imaged bilayer stack containing the relief image with an aqueous liquid optionally containing a surfactant,
f) applying a fixer solution to the imaged bilayer stack to stabilize (fix) the relief image,
g) applying an optional bake step,
h) rinsing the imaged bilayer stack containing the stabilized image with a liquid optionally containing a surfactant,
i) applying a second optional bake step,
j) applying in a second coating step a second photosensitive composition onto the imaged bilayer stack to produce a multilayer stack,
k) exposing the second photosensitive composition in the multilayer stack in an imagewise manner to actinic radiation in a second exposure step to produce a second pattern in which the placement of the second exposure pattern is offset from the first exposure pattern by a predetermined amount,
l) developing the exposed second photosensitive composition in an aqueous base developer to produce an imaged multilayer stack containing a second relief image, and
m) rinsing the imaged multilayer stack containing the second relief image with an aqueous liquid optionally containing a surfactant;
   wherein the first and second photosensitive compositions each comprise a photoacid generator and a substantially aqueous base insoluble polymer whose aqueous base solubility increases upon treatment with acid and further comprises an anchor group, and the fixer solution comprises a polyfunctional fixer compound which is reactive with the anchor group, but does not contain silicon and wherein the semiconductor substrate stays within a lithographic cell from at least the first coating step until at least after the final exposure.

### DETAILED DESCRIPTION OF THE INVENTION

### Definition of Terms

In the context of this invention, the term multilayer shall be taken to mean at least three film layers. A fixer group is defined as a reactive group on the compounds employed in the treatment solution (fixer solution) to react with an anchor group on the polymer in the photosensitive composition. An Anchor group is defined as a functional group on the photoresist polymer that is reactive to the fixer group. The terms photoresist, resist, and photosensitive composition are used interchangeably. The term imaging layer refers to a coating of the photoresist/photosensitive composition/resist on the substrate or on top of various coating(s) on the substrate. The terms coating and film may be used interchangeably. Unless otherwise specified, the term % refers to weight %.

The term lithography cell refers to group of processing modules connected together such that the semiconductor substrate can move from one module to another for the next process step without leaving the highly purified and clean atmosphere of the lithography cell. A typical lithography cell contains at least an exposure system, spin coating modules for coating and edge bead removal, bake modules, and development modules.

### BRIEF DESCRIPTION OF THE DRAWINGS

FIG. 1 illustrates an overview of a prior art double exposure patterning and etching processes.

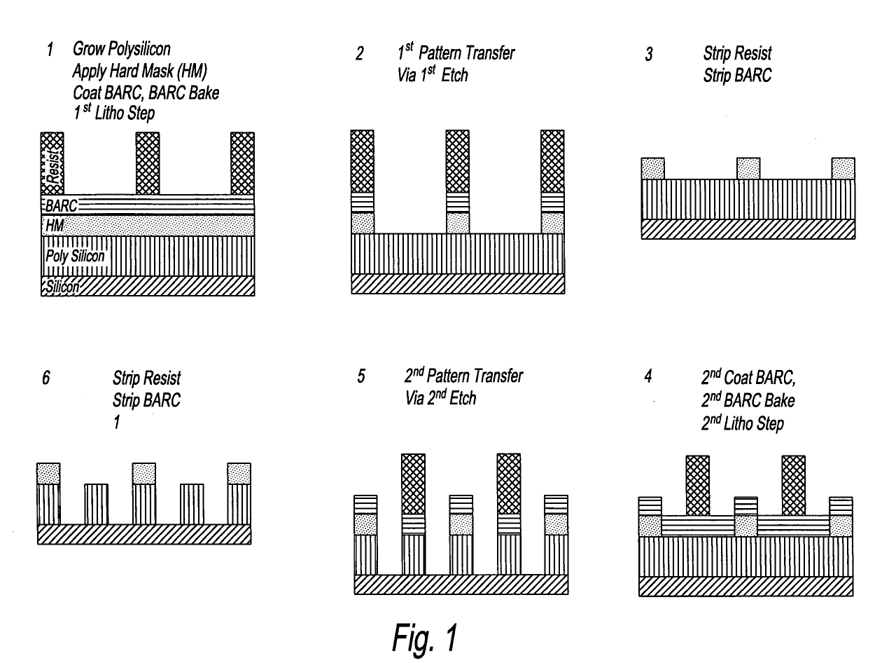

FIG. 2 illustrates an overview of a double exposure patterning process of this invention plus etching processes.

FIG. 3 illustrates a double patterned image formed according to this invention.

The present invention relates to a multiple exposure patterning process to manufacture relief images used in manufacture of a semiconductor device. The present invention is a process for manufacturing a semiconductor device using a multiple exposure patterning, comprising:
a) providing a coated semiconductor substrate with an antireflective coating or an underlayer,
b) applying in a first coating step, a first photosensitive composition over the coated semiconductor substrate to produce a bilayer stack,
c) exposing the first photosensitive composition in the bilayer stack in a imagewise manner to actinic radiation in a first exposure step to produce a first pattern,
d) developing the exposed first photosensitive composition in an aqueous base developer to produce an imaged bilayer stack containing a relief image,
e) rinsing the imaged bilayer stack containing the relief image with an aqueous liquid optionally containing a surfactant,
f) applying a fixer solution to the imaged bilayer stack to stabilize (fix) the relief image,
g) applying an optional bake step,
h) rinsing the imaged bilayer stack containing the stabilized image with a liquid optionally containing a surfactant,
i) applying a second optional bake step,
j) applying in a second coating step a second photosensitive composition onto the imaged bilayer stack to produce a multilayer stack,
k) exposing the second photosensitive composition in the multilayer stack in an imagewise manner to actinic radiation in a second exposure step to produce a second pattern in which the placement of the second exposure pattern is offset from the first exposure pattern by a predetermined amount,
l) developing the exposed second photosensitive composition in an aqueous base developer to produce an imaged multilayer stack containing a second relief image, and
m) rinsing the imaged multilayer stack containing the second relief image with an aqueous liquid optionally containing a surfactant;
   wherein the first and second photosensitive compositions each comprise a photoacid generator and a substantially aqueous base insoluble polymer whose aqueous base solubility increases upon treatment with acid and further comprises an anchor group, and the fixer solution comprises a polyfunctional fixer compound which is reactive with the anchor group, but does not contain silicon and wherein the semiconductor substrate stays within a lithographic cell from at least the first coating step until at least after the final exposure.

In preferred embodiment, the present invention is a multiple exposure patterning process comprising:
a) providing a coated semiconductor substrate coated with a cured underlayer (UL),
b) applying in a first coating step, a first photosensitive composition over the coated semiconductor substrate to produce a bilayer stack,
c) exposing the first photosensitive composition in the bilayer stack in a imagewise manner to actinic radiation in a first exposure step to produce a first pattern,
d) developing the exposed first photosensitive composition in an aqueous base developer to produce an imaged bilayer stack containing a relief image,
e) rinsing the imaged bilayer stack containing the relief image with an aqueous liquid optionally containing a surfactant,
f) applying a fixer solution to the imaged bilayer stack to stabilize (fix) the relief image,
g) applying an optional bake step,
h) rinsing the imaged bilayer stack containing the stabilized image with a liquid optionally containing a surfactant,
i) applying a second optional bake step,
j) applying in a second coating step a second photosensitive composition onto the imaged bilayer stack to produce a multilayer stack,
k) exposing the second photosensitive composition in the multilayer stack in an imagewise manner to actinic radiation in a second exposure step to produce a second pattern in which the placement of the second exposure pattern is offset from the first exposure pattern by a predetermined amount,
l) developing the exposed second photosensitive composition in an aqueous base developer to produce an imaged multilayer stack containing a second relief image, and
m) rinsing the imaged multilayer stack containing the second relief image with an aqueous liquid optionally containing a surfactant;
   wherein the first and second photosensitive compositions each comprise a photoacid generator and a substantially aqueous base insoluble, silicon containing polymer whose aqueous base solubility increases upon treatment with acid and further comprises an anchor group, and the fixer solution comprises a polyfunctional compound reactive with the anchor group, but does not contain silicon and wherein the semiconductor substrate stays within a lithographic cell from at least the first coating step until at least after the final exposure.

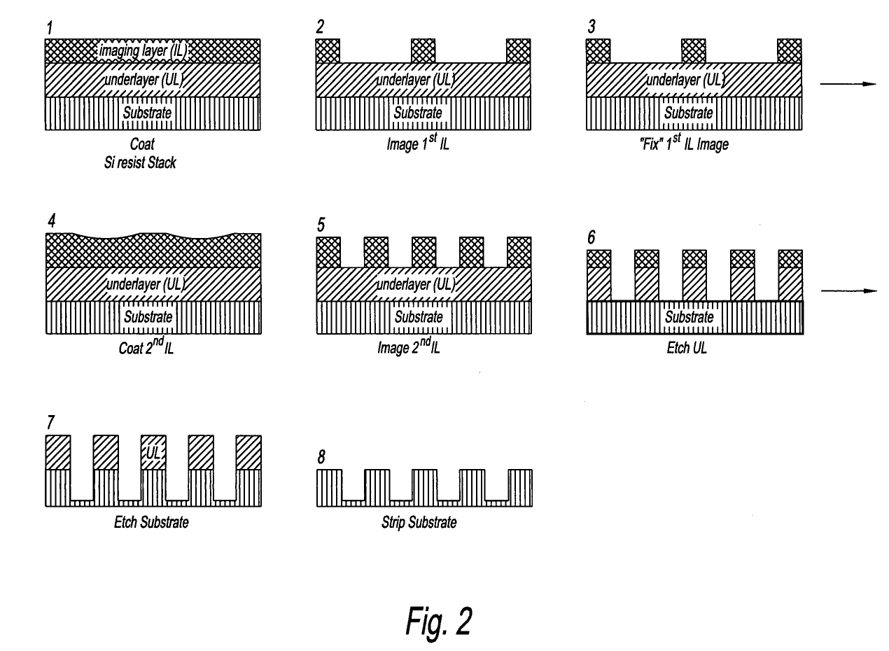

An overview of an example of the multiple patterning process of the invention employing two exposures is provided in FIG. 2 for this preferred embodiment. The drawing marked 1 in FIG. 2 illustrates the situation after the underlayer and imaging layer (silicon containing photoresist) have been coated on the substrate. The drawing marked 2 in FIG. 2 illustrates the processed substrate after the first lithographic process steps. The imaging layer has been patterned over the underlayer. The drawing marked 3 in FIG. 2 illustrates the situation after the fixer treatment process. The exposed surfaces of the resist pattern have been crosslinked. The drawing marked 4 in FIG. 2 illustrates the situation after the second photosensitive composition coating preparation. The drawing marked 5 in FIG. 2 illustrates the situation after exposing and developing the second photosensitive composition coating. The drawing marked 6 in FIG. 2 illustrates the situation after the double patterned photoresist stack has been subjected to an underlayer etch step. The drawing marked 7 in FIG. 2 illustrates the situation after the substrate etch. The drawing marked 8 in FIG. 2 illustrates the situation after the underlayer is stripped.

The semiconductor substrate may be, for example, semiconductor materials such as a silicon wafer, compound semiconductor (III-V) or (II-VI) wafer, a ceramic, glass or quartz substrate. These substrates may also contain films, (e.g. hardmasks) or structures used for electronic circuit fabrication such as organic or inorganic dielectrics, copper or other wiring metals.

The substrate may have optionally been dehydration baked. This dehydration bake is typically carried out by heating to above 200° C. at atmospheric pressure or under vacuum for a period of about 1 minute to about 30 minutes depending on the heating method. Any suitable method of heating known to those skilled in the art may be employed. Examples of suitable heating means include, but are not limited to, hot plates, convection ovens or vacuum ovens.

The substrate may also have been optionally subjected to a pre-wetting with a suitable solvent. Any suitable method of treatment of the substrate with the solvent known to those skilled in the art may be employed. Examples include treatment of the substrate with solvent by spraying, streaming or immersing the substrate into the solvent. The time and temperature of treatment will depend on the particular substrate, and method, which may employ elevated temperatures. Any suitable solvent or solvent blend may be employed. Preferred are solvents capable of dissolving the components of the Photosensitive Composition.

The substrate may have also been optionally treated with an adhesion promoter. This process is commonly revered to as priming. Any suitable method of treatment of the substrate with adhesion promoter known to those skilled in the art may be employed. Examples include treatment of the substrate with adhesion promoter vapors or contacted the substrate with the adhesion promoter by spraying, streaming, immersing or dipping. The time and temperature of treatment will depend on the particular substrate, adhesion promoter, and method, which may employ elevated temperatures. The preferred treatment method to apply an adhesion promoter layer on the substrate is vapor priming. Any suitable external adhesion promoter may be employed. The preferred adhesion promoter is a hexaalkyldisilane containing adhesion promoter. More preferably, the adhesion promoter contains hexamethyldisilane. Additional suitable adhesion promoters are described in “Silane Coupling Agent” Edwin P. Plueddemann, 1982 Plenum Press, New York.

In this preferred embodiment, the substrate is coated with an underlayer. Underlayers are employed in a bilayer resist system primarily to provide an etch mask for image transfer into the substrate. Underlayers absorb most of the actinic light that attenuates standing wave effects. They also prevent deactivation of the acid catalyst at the resist/substrate interface. In addition underlayers may substantially planarize the substrate before the next lithography step.

Any suitable method to apply the underlayer over the substrate may be used. Coating methods include, but are not limited to spray coating, spin coating, offset printing, roller coating, screen printing, extrusion coating, meniscus coating, curtain coating, dip coating, and immersion coating.

After the coating step, the tacky film of underlayer composition is baked to cure it. The baking may take place at one temperature or multiple temperatures in one or more steps. Baking may take place on a hot plate or in various types of ovens known to those skilled in the art. Suitable ovens include ovens with thermal heating, vacuum ovens with thermal heating, and infrared ovens or infrared track modules. Typical times employed for baking will depend on the chosen baking means and the desired time and temperature and will be known to those skilled in the art. A preferred method of baking is on a hot plate. When baking on a hot plate employing a two step process, typical times range from about 0.5 minute to about 5 minutes at temperatures typically between about 80° C. to 130° C., followed by a cure step for about 0.5 minutes to about 5 minutes typically between about 170° C. to about 250° C. In a one step process, the underlayer film is cured for about 0.5 minutes to about 5 minutes typically between about 170° C. to about 250° C. The underlayer-coated substrate is then allowed to cool. Preferably, the thermally curable polymer composition is cured at temperatures between about 150° C. to about 250° C. and more preferably between temperatures of 180° C. to 220° C. The preferable cure times are from about 30 to 180 seconds and more preferably from about 60 to about 120 seconds.

The underlayer is present at a thickness necessary to enable the lithographic patterning of the imaging layer and to provide enough protection to the substrate for its subsequent treatment (i.e. etching). Preferably the Underlayer thickness is from about 80 nm to about 1200 nm. A more preferred Underlayer thickness range is from about 150 nm to about 500 nm. The preferred Underlayer thickness is from 160 nm to 300 nm.

The underlayer may be any suitable film forming polymer composition capable of providing etch selectivity to the underlying substrate as well as antireflective properties to improve the lithographic processing window of the photosensitive composition. Underlayers are generally comprised of curable, hydroxyl containing, resin binders, crosslinking agents and acid generators. When these coatings are heated, the thermal acid generator produces an acid that protonates the cross-linking agent resulting in a very strong electrophilic group. This group reacts with the hydroxyl group on the polymer forming a cured cross-linked polymer matrix. Examples of suitable underlayer compositions can be found in U.S. Pat. Nos. 6,054248, 6,323,287, 6,610,808 and US Patent Application Publication No. 2005/0238997. Suitable resin binders include, but are not limited to, phenolic resins, poly(meth)acrylate resins, styrene-allyl alcohol copolymer resins, copolymers of isobornyl methacrylate, hydroxystyrene and polycyclic polymers.

Cross-linkers employed in underlayer compositions may have amino or phenolic functional groups such as methylolated and/or methylolated and etherified guanamines, methylolated and/or methylolated and etherified melamines and the like. Examples of suitable melamine cross-linking agents are methoxyalkylmelamines such as hexamethoxymethylmelamine, trimethoxymethylmelamine, hexamethoxyethylmelamine, tetramethoxy-ethylmelamine, hexamethoxypropylmelamine, pentamethoxypropylmelamine, and the like. The preferred melamine cross-linking agent is hexamethoxymethyl-melamine. Preferred aminocrosslinking agents are MW100LM melamine crosslinker from Sanwa Chemical Co. Ltd., Kanaxawa-ken, Japan, Cymel 303 and Powderlink 1174 from Cytec Industries, West Patterson, N.J. Examples of suitable phenolic cross-linking agents are disclosed in U.S. Pat. Nos. 5,488,182 and 6,777,161 and US Patent application 2005/0238997. 4,4′-[1,4-phenylenebis(methylidene)]bis(3,5-dihydroxymethyl phenol), 4,4′-[1,4-phenylenebis(1-ethylidene)]bis(3,5-dihydroxymethyl phenol), 4,4′-[1,4-phenylenebis(1-propylidene)]bis(3,5-dihydroxymethyl phenol), 4,4′-[1,4-phenylenebis(1-butylidene)]bis(3,5-dihydroxymethyl phenol), 4,4′-[1,4-phenylenebis(1-pentylidene)]bis(3,5-dihydroxymethyl phenol), 4,4′-[1,4-phenylenebis(1-methyl ethylidene)]bis(3,5-dihydroxymethyl phenol), 4,4′-[1,4-phenylenebis(1-ethyl propylidene)]bis(3,5-dihydroxymethyl phenol), 4,4′-[1,4-phenylenebis(1-propyl butylidene)]bis(3,5-dihydroxymethyl phenol), 4,4′-[1,4-phenylenebis(1-butyl pentylidene)]bis(3,5-dihydroxymethyl phenol), 4,4′-[1,3-phenylenebis(methylidene)]bis(3,5-dihydroxymethyl phenol), 4,4′-[1,3-phenylenebis(1-methyl ethylidene)]his (3,5-dihydroxymethyl phenol), 4,4′-[1,3-phenylenebis(1-ethyl propylidene)]bis(3,5-dihydroxymethyl phenol), 4,4′-[1,3-phenylenebis(1-propyl butylidene)]bis(3,5-dihydroxymethyl phenol) and 4,4′-[1,3-phenylenebis(1-butyl pentylidene)]bis(3,5-dihydroxymethyl phenol) are given as specific examples of hydroxymethyl-substituted polyfunctional phenols as crosslinker precursor.

The Underlayer composition of the present invention further comprises one or more thermal acid generators (TAGs). TAGs useful in this invention are latent acid catalyst(s), which may be classified as either ionic or nonionic TAGs. For example the sulfonic esters of organic acids belong to the class of nonionic TAGs. Examples of nonionic sulfonate derivatives useful as TAGs include, but are not limited to, cyclohexyltosylate, 2-nitrobenzyl tosylate, 2-nitrobenzyl methylsulfonate, 2,6-dinitro benzyl p-toluenesulfonate, 4-dinitrobenzyl-p-toluenesulfonate, 1,2,3-tris(methane sulfonyloxy)benzene, 1,2,3-tris(methanesulfonyloxy)benzene, 1,2,3-tris(ethanesulfonyloxy)benzene, 1,2,3-tris(propanesulfonyloxy)benzene, 1,2,3-tris(trifluoromethane sulfonyloxy)benzene, 1,2,3-tris(p-toluene sulfonyloxy)benzene, 4-nitrobenzyl 9,10-dimethoxyanthracene-2-sulfonate and the like.

Suitable latent acid catalyst TAGs classified as ionic TAGs include organic acid salts represented by Structure IVa:

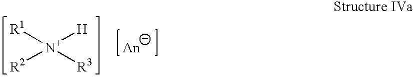

wherein R¹, R² and R³ are independently a hydrogen atom, substituted or unsubstituted alkyl, substituted or unsubstituted cycloalkyl, substituted or unsubstituted alicyclic, partially or completely halogen substituted alkyl, substituted or unsubstituted aryl, substituted or unsubstituted alkoxy groups, or any two of R¹, R² and R³ or all of R¹, R² and R³ are part of a cyclic or polycyclic group which may contain an oxygen, sulfur or nitrogen hetero atom; An⁻ is selected from the group consisting of sulfonates of substituted or unsubstituted C₁-C₁₂ alkyl, partially or completely halogen substituted C₁-C₁₂ alkyl, C₄-C₁₅ cycloalkyl, partially or completely halogen substituted C₄-C₁₅ cycloalkyl, C₇-C₂₀ alicyclic or C₆-C₂₀ aromatic groups; disulfonates of substituted or unsubstituted C₁-C₁₂ alkylene, partially or completely halogen substituted C₁-C₁₂ alkylene, C₄-C₁₅ cycloalkylene, partially or completely halogen substituted C₄-C₁₅ cycloalkylene, C₇-C₂₀ alicyclic or C₆-C₂₀ aromatic groups; sulfonamides of Structure Va wherein R¹¹ and R¹² are

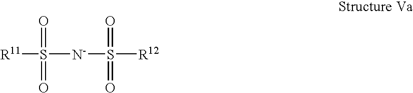

wherein R¹¹ and R¹² are independently substituted or unsubstituted alkyl, substituted or unsubstituted cycloalkyl, substituted or unsubstituted alicyclic, partially or completely halogen substituted alkyl, or substituted or unsubstituted aryl groups; and methides of Structure Vb

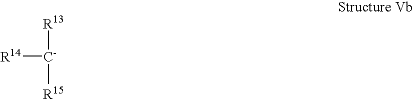

wherein R¹³, R¹⁴ and R¹⁵ are independently C₁-C₁₀ perfluoroalkylsulfonyl groups.

Suitable examples of amines which can be used to generate the ammonium ion include, but are not limited to, tributylamine, triisobutylamine, dicyclohexylamine, N-ethyldicyclohexylamine, 1-methylpyrrolidine, 1-butylpyrrolidine, piperidine, 1-methylpiperidine, hexamethyleneimine, heptamethyleneimine, tropane, quinuclidine, 4-methyl-1-oxa-3-aza-cyclopentane, 4,4-dimethyl-1-oxa-3-aza-cyclopentane, 4,4-diethyl-1-oxa-3-aza-cyclopentane, 4,4-diisopropyl-1-oxa-3-aza-cyclopentane, 4,4-ditert-butyl-1-oxa-3-aza-cyclopentane, 4,4-dimethyl-1-oxa-3-aza-cyclohexane, 1-aza-3,7-dioxa-5-ethylbicyclo[3.3.0]octane, 1-aza-3,7-dioxa-5-methylbicyclo[3.3.0]octane, 1-aza-3,7-dioxa-5-tertbutylbicyclo[3.3.0]octane and the like. Examples of suitable TAGs of this type can be found in U.S. Pat. Nos. 3,474,054, 4,200,729, 4,251,665, and 5,187,019 herein incorporated by reference.

Another suitable type of latent acid catalyst classified as an ionic TAG are benzylammonium salts of acids represented by Structure IVb and IVc.

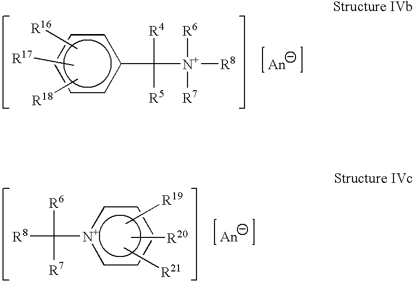

wherein R⁴ and R⁵ are independently hydrogen, alkyl or halogen groups; ⁶ and R⁷ are independently C₁-C₁₀ alkyl or alkoxy groups; R⁸ is a phenyl group; R¹⁶, R¹⁷, R¹⁸, R¹⁹, R²⁰ and R²¹ are independently hydrogen, alkyl or halogen groups and An⁻ has the same meaning as defined above.

Suitable examples of benzylic amines which can be used to generate the ammonium ion include, but are not limited to, N-(4-methoxybenzyl)-N,N-dimethylaniline, N-(benzyl)-N,N-dimethylaniline, N-(benzyl)-N,N-dimethyltoluidine, N-(4-methylbenzyl)-N,N-dimethylaniline, N-(4-methoxybenzyl)-N,N-dimethylaniline, N-(4-chlorobenzyl)-N,N-dimethylaniline, N-(t-butylbenzyl)-dimethylpyridine and the like. The ammonium salts may also be quaternary and synthesized by other methods. Examples of this class of ionic TAG may be found in U.S. Pat. Nos. 5,132,377, 5,066,722, 6,773,474 and U.S. Patent Publication No. 2005/0215713, herein incorporated by reference.

The TAGS useful for the invention are those compounds capable of generation of free acid at the bake temperature of the films formed from the Underlayer composition. Typically these temperatures range from about 90° C. to about 250° C. Preferably the TAG will have a very low volatility at temperatures between 170-220° C. TAGs employed in this invention can be purchased commercially (e.g. from King Industries, Norwalk, Conn. 06852, USA), prepared by published synthetic procedures or synthetic procedures known to those skilled in the art.

The thermal acid generators described above should not be considered photoacid generators. Any sensitivity that the thermal acid generators may have to UV light should be very poor and they cannot practically be used in photolithography as photoacid generators.

The underlayer composition may further contain small amounts of a photoacid generator in order to optimize clean development and vertical profiles at the interface with the photosensitive composition. Suitable photoacid generators are described below when discussing the photosensitive compositions.

The underlayer composition may further comprise a surfactant. Suitable classes of surfactants include polysiloxanes, anionic, cationic, nonionic, and amphoteric surfactants. Nonionic surfactants which contain fluorine atoms and polysiloxanes are preferred.

Typically, a thermally curable underlayer composition contains, on a total solids basis, about 65 to 95 wt. % of the underlayer polymer. The amount of the cross-linking agent in underlayer composition is from about 3 to about 30 wt. %. The amount of the thermal acid generator in the thermally curable polymer composition is from about 0.1 to about 10 wt %. The concentration of a photoacid generator, if employed in the underlayer composition, is from about 0.1 to about 10 wt %.

Solvents suitable for underlayer compositions include alcohols, ketones, ethers and esters, such as 1-pentanol, propyleneglycol monomethyl ether (PGME), 2-heptanone, cyclopentanone, cyclohexanone, γ-butyrolactone, ethylene glycol monomethyl ether, ethylene glycol monoethyl ether, 2-methoxyethyl acetate, ethylene glycol monoethyl ether acetate (PGMEA), propylene glycol monoethyl, propylene glycol methyl ether acetate, methyl lactate, ethyl lactate, methyl 3-methoxypropionate, ethyl ethoxypropionate, methyl pyruvate, ethyl pyruvate, propyl pyruvate, N-methyl-2-pyrrolidone, ethylene glycol monoisopropyl ether, diethylene glycol monoethyl ether, diethylene glycol dimethyl ether and the like. The more preferred solvents for the Underlayer composition are 2-heptanone, propylene glycol monomethyl alcohol, propylene glycol methyl ether acetate, ethyl lactate and mixtures thereof.

These underlayer compositions are carefully engineered to address a variety of issues. For example some semiconductor manufacturing deep UV exposure tools utilize the same wavelength of light to both expose the resist and to align the exposure mask to the layer below the resist. If the underlayer layer is too absorbent, the reflected light needed for alignment is too attenuated to be useful. However, if the underlayer layer is not absorbent enough, standing waves may occur. Throughput is negatively impacted if high curing temperatures or curing times are needed, while low curing temperatures (i.e. <50° C.) will lead to premature aging of the underlayer composition. In addition the uncured underlayer composition should be compatible with at least one edge bead remover acceptable to the semiconductor industry, while intermixing of the cured underlayer with the casting solvents of the photosensitive composition used as topcoat is not desirable.

The underlayer-coated substrate is coated with a first photosensitive composition and baked to produce the bilayer stack. Coating and baking equipment and techniques described above for the underlayer may be employed for the photosensitive composition. Typical times employed for baking will depend on the chosen baking means, the particular photoresist, the desired time and the desired temperature and will be known to those skilled in the art. A preferred baking method is hot plate baking. When baking on a hot plate, typical times range from about 0.5 minute to about 5 minutes at temperatures typically between about 80° C. to about 140° C. Optimum bake parameters may vary depending on the photoresist and solvent employed.

The imaging layer thickness in the bilayer stack is optimized for lithographic performance, and the need to provide oxygen plasma etch resistance for the image transfer into the Underlayer film. Preferably the imaging layer has a thickness from about 50 nm to about 500 nm. A more preferred imaging layer thickness range is from about 100 nm to about 250 nm. The preferred imaging layer thickness is from 110 nm to 170 nm.

The photosensitive composition employed in the process of this invention must have certain characteristics. It must form an excellent film with few or no defects, be soluble in casting solvents of low toxicity, be poorly soluble or insoluble in the fixer solution, be capable of high resolution imaging, be capable of reacting with a fixer solution described below and be oxygen plasma etch resistant. Such characteristics are usually found in silicon containing chemically amplified resists sensitive to radiation in the deep and far UV region. Such resists will typically comprise a polymer, a photoacid generator (PAG), a solvent, and optional components such as diffusion control agents and surfactants.

The silicon-containing polymer useful in the invention is a material with a molecular weight of from about 1000 to about 100,000 amu. This material is preferably a poorly alkali soluble or alkali insoluble silicon-containing polymer comprising one or more blocked (masked) alkali solubilizing group (acid sensitive group). The functionality blocking the alkali solubilizing group is acid sensitive. The presence of an acid catalyzes the deblocking of the alkali solubilizing group and renders the polymer alkali soluble. Suitable alkali solubilizing groups include, but are not limited to, carboxylic acids, sulfonic acid, phenols, acidic alcohols, hydroxyimides, hydroxymethylimides, and silanols. Suitable alkali solubilizing groups are further described in US Patent Application Publication No. 2006/0110677. Monomeric units containing blocked alkali solubilizing groups may or may not contain silicon. Examples of monomeric units containing alkali soluble monomeric units after deblocking include, but are not limited to,

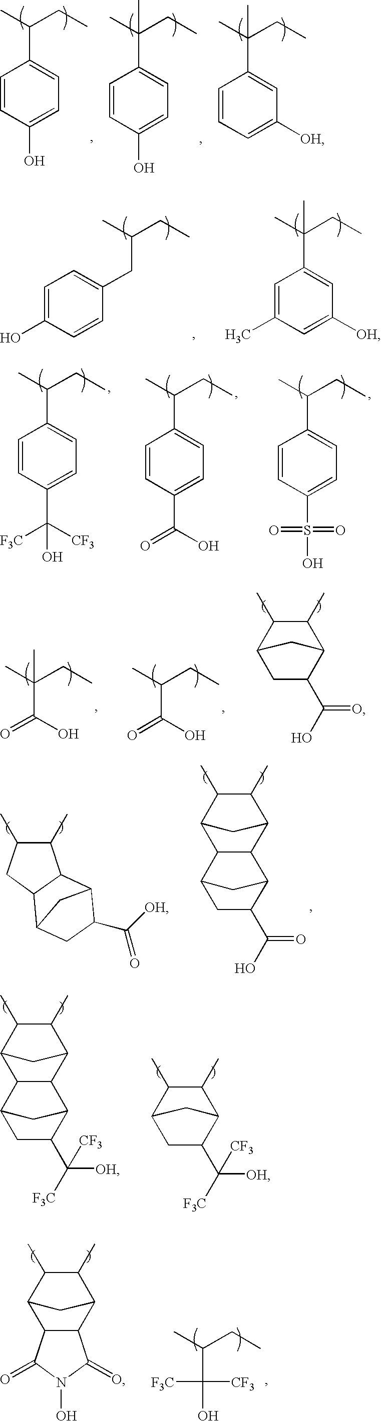

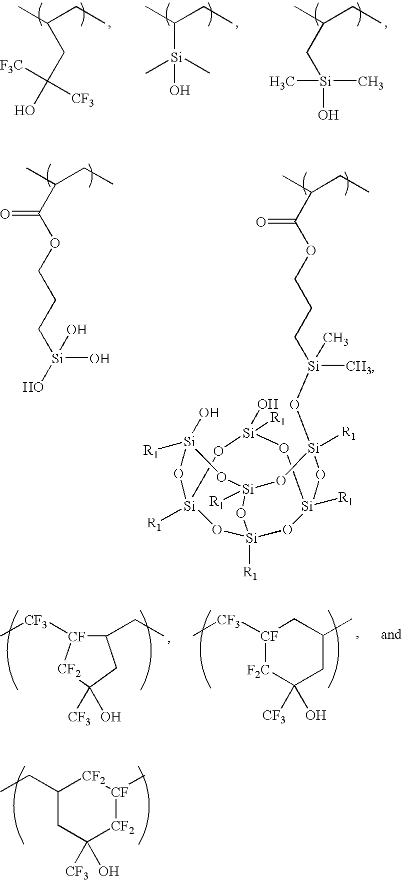

Any number of acid-sensitive protecting groups, known to those skilled in the art, may be employed. Preferred acid-sensitive protecting groups include tertiary alkyl groups, α-alkoxy alkyl groups, arylisopropyl and alicyclic substituted isopropyl groups. Specific acid-sensitive protecting groups include, but are not limited to, t-butyl, 1,1-dimethylpropyl, 1-methyl-1-cyclohexyl, 2-isopropyl-2-adamantyl, tetrahydropyran-2-yl, methoxy methyl, ethoxy ethyl and the like. Examples of suitable blocked alkali solubilizing groups include, but are not limited to, tertiary alkyl esters such as t-butyl esters, α alkoxy esters, alpha alkoxyalkyl aromatic ethers, t-butoxyphenyl, t-butoxyimido, t-butoxycarbonyloxy, and t-butoxymethylimido. Examples of blocked alkali solubilizing groups can be found in U.S. Pat. Nos. 5,468,589, 4,491,628, 5,679,495, 6,379,861, 6,329,125, 6,440,636, 6,830867, 6,136,501 and 5,206,317, which are incorporated herein by reference.

Examples of suitable monomers containing blocked alkali solubilizing groups include, but are not limited to, monomers represented by the structures below:

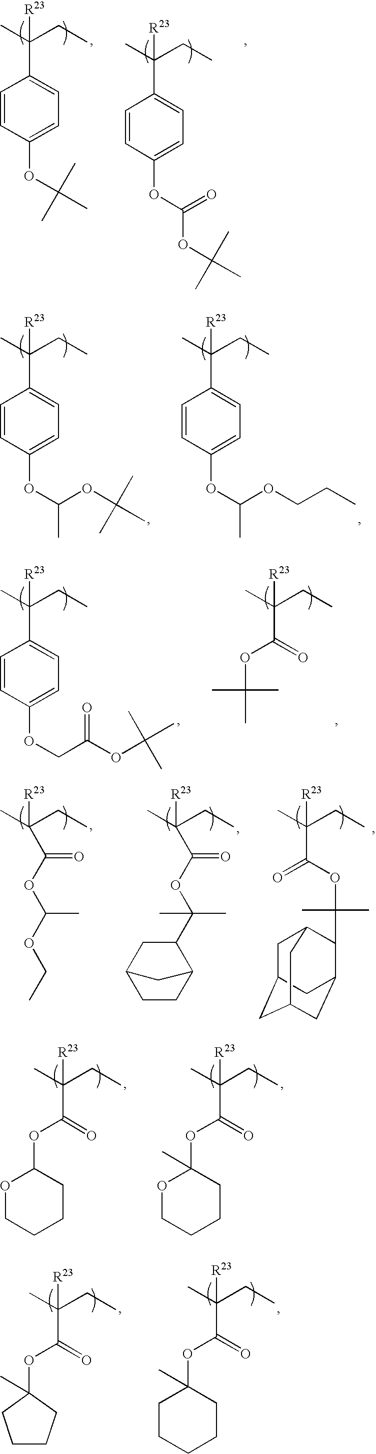

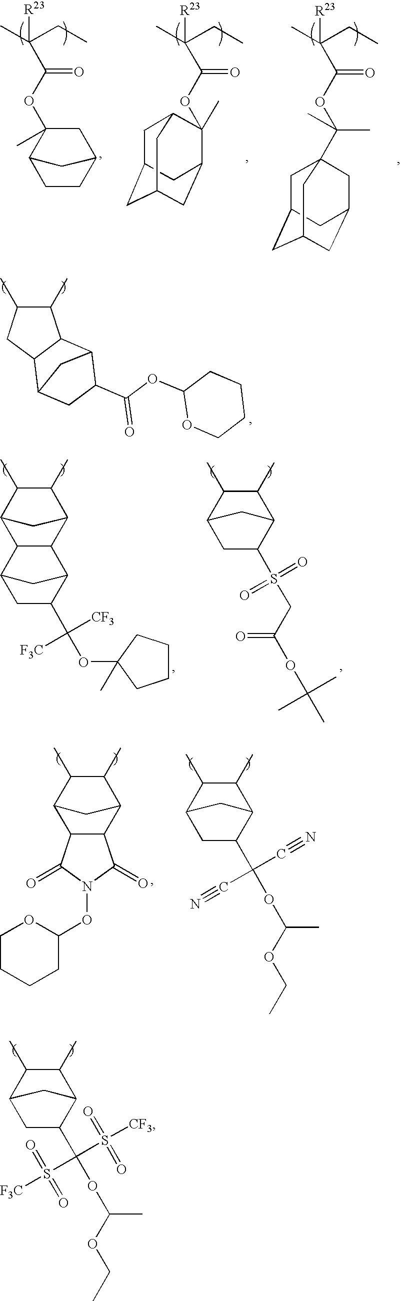

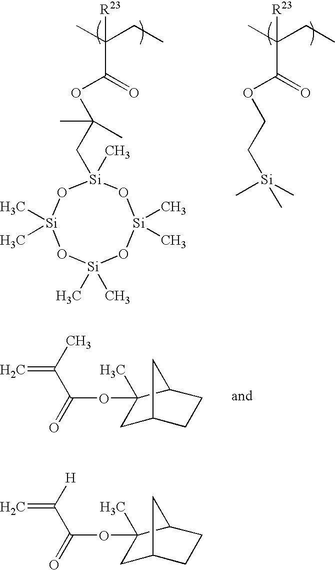

wherein R²³ is independently a hydrogen atom, a C₁-C₃ alkyl group, or a C₁-C₃ perfluorinated alkyl group. Examples of preferred R²³ groups include, but are not limited to, hydrogen, methyl or trifluoromethyl. Additional suitable monomers containing blocked alkali solubilizing groups can be found in U.S. Pat. Nos. 5,468,589, 4,491,628, 5,679,495, 6,379,861, 6,329,125, 6,440,636, 6,830867, and 5,206,317.

In this preferred embodiment of the invention, the polymer of the photosensitive composition employed in the process of this invention further comprises silicon. Suitable polymers are those with silicon content of about 5 to about 30% silicon by weight. Preferred polymers are those with silicon content from about 8 to about 25% silicon by weight.

Monomeric units containing one or more silicon moieties may or may not have blocked alkali solubilizing groups. Examples of suitable monomers containing a least one silicon moiety include, but are not limited to, structures VI-IX.

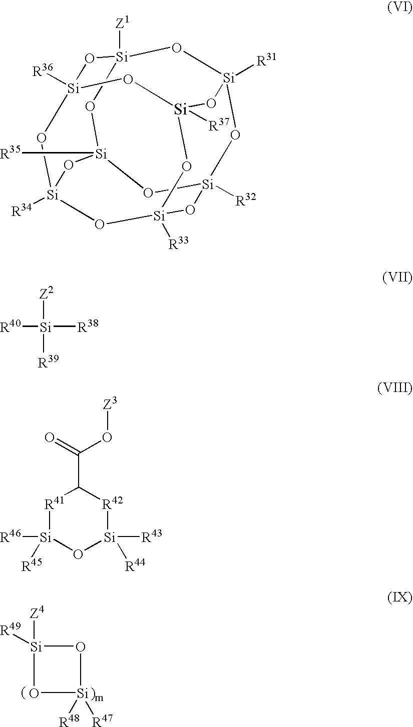

wherein Z¹, Z², Z³, and Z⁴ are each independently a P-Q group, wherein P is a polymerizable group, preferably a moiety containing an ethylenically unsaturated polymerizable group and Q is a single bond or a divalent bridging group. This divalent bridging group may include, but is not limited to, divalent heteroatoms, a divalent acetal, ketal, carbonate group or carboxylic acid ester, a C₁-C₁₂ linear, branched, cyclic or polycyclic alkylene group, a dialkyl siloxyl or a C₆-C₁₄ arylene group. Examples of P groups include, but are not limited to, linear or cyclic alkenes, C₁-C₆ linear vinyl ethers, C₂-C₈ linear or cyclic alkyl acrylic esters, styrene and hydroxyl styrene. Examples of preferred polymerizable groups include, but are not limited to, vinyl, allyl, 1-butenyl, 1-vinyloxyethyl, 2-ethyl acryloyl, 2-propylacryloyl or 2-cyclohexyl acryloyl. Examples of divalent bridging groups include, but are not limited to, methylene, ethylene, propylene, butylene, cyclopentylene, cyclohexylene, bicyclo[2.2.1]heptylene, tetracyclo[4.4.1^{2,5}.1^{7,10}.0]dodecylene, —OC(CH₃)OCH₂—, —CH₂OC(CH₃)₂OC₂H₄—, —C(O)OC(O)CH₂—, —C(O)OC2H4-, —O—, dimethyl siloxyl, phenylene, biphenylene, and naphthalene.

R³¹, R³², R³³, R³⁴, R³⁵R³⁶ and R³⁷ are each the same and selected from the group consisting of
(1) a linear, branched or cyclic alkyl or a substituted or unsubstituted alicyclic group, having 1 to 20 carbon atoms;
(2) a linear, branched or cyclic fluoroalkyl or fluorine substituted alicyclic group having 1 to 20 carbon atoms; and
(3) a polar group, selected from
   (a) (CH₂)ₙ—OR⁵⁰,
      where n is an integer of from about 2 to about 10 and R⁵⁰ is a hydrogen atom, a linear, branched and cyclic alkyl or alicyclic group having 1 to 20 carbon atoms, or an α-alkoxy alkyl group;
   (b) (CH₂)ₒ—(C═O)—OR⁵¹,
      where o is an integer of from about 2 to about 10 and R⁵¹ is a hydrogen atom, a linear, branched and cyclic alkyl or alicyclic group having 1 to 20 carbon atoms, or an acid sensitive protecting group;
   (c) (CH₂)ₚ—C(CF₃)R⁵²—OR⁵³
      where p is an integer of from about 2 to about 10 and R⁵² is a hydrogen atom or fluoromethyl, difluoromethyl or trifluoromethyl and R⁵³ can be a hydrogen atom or a linear, branched and cyclic alkyl or alicyclic group having 1 to 20 carbon atoms; and
   (d) (CH₂)ᵣ—O—(C═O)R⁵⁴,
      where r is an integer of from about 2 to about 10 and R⁵⁴ is a linear, branched and cyclic alkyl or alicyclic group having 1 to 20 carbon atoms;

R³⁸, R³⁹, and R⁴⁰ are independently a linear, branched or cyclic C₁-C₂₀ alkyl group, linear branched or cyclic fluoroalkyl group, substituted or unsubstituted C₃-C₂₀ alicyclic group, Structure XII or Structure XIII

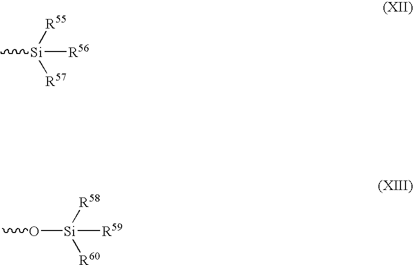

wherein R⁵⁵, R⁵⁶, R⁵⁷R⁵⁸, R⁵⁹, and R⁶⁰ are independently a linear, branched or cyclic C₁-C₂₀ alkyl group, linear branched or cyclic fluoroalkyl group, or substituted, unsubstituted C₃-C₂₀ alicyclic group;

R⁴¹ and R⁴² are independently a C₁-C₃ alkylene group and R⁴³, R⁴⁴, R⁴⁵ and R⁴⁶ are independently a C₁-C₁₀ linear or cyclic alkyl group, a C₆-C₁₀ substituted or unsubstituted group, a C₁-C₈ alkoxy methyl group or a C₁-C₈ alkoxy ethyl group. Examples of R⁴¹ and R⁴² include, but are not limited to, a methylene, ethylene, and propylene group, with a methylene group being more preferred. Examples of R⁴³, R⁴⁴, R⁴⁵ and R⁴⁶ groups are, but are not limited to, methyl, ethyl, propyl, isopropyl, cyclopropyl, cyclopentyl, cyclohexyl, phenyl, 4-methylphenyl, methoxy methyl, ethoxy methyl and methoxy ethyl;

R⁴⁷, R⁴⁸ and R⁴⁹ are independently linear, branched and cyclic C₁-C₂₀ alkyl or alicyclic groups, partially substituted or fully substituted cyclic C₁-C₂₀ alkyl or alicyclic groups, or substituted or unsubstituted C₆-C₂₀ aryl groups; m is an integer of from about 2 to about 10. Preferably m is 2 to 6, more preferred 2-3, most preferred 3.

Examples of R⁴⁷, R⁴⁸ and R⁴⁹ include, but are not limited to, methyl, trifluoromethyl, ethyl, n-propyl, isopropyl, n-butyl, isobutyl, sec-butyl, tert-butyl, cyclopentyl, cyclohexyl, heptyl, isooctyl, cyclooctyl, nonyl, decyl, pendecyl, eicosyl, hydroxycyclohexyl, dihydroxycyclohexyl, bicyclo[2.2.1]heptyl, hydroxybicyclo[2.2.1]heptyl, carboxybicyclo[2.2.1]heptyl, phenyl, tolyl, and naphthyl. Preferred examples of R⁴⁷, R⁴⁸ and R⁴⁹ include, but are not limited to, methyl, ethyl, n-propyl, isopropyl, n-butyl, isobutyl, sec-butyl, tert-butyl, cyclopentyl, cyclohexyl, cyclooctyl, dihydroxycyclohexyl, bicyclo[2.2.1]heptyl, hydroxybicyclo[2.2.1]heptyl, carboxybicyclo[2.2.1]heptyl, and naphthyl.

Examples of silicon-containing monomeric units include, but are not limited to the following structures:

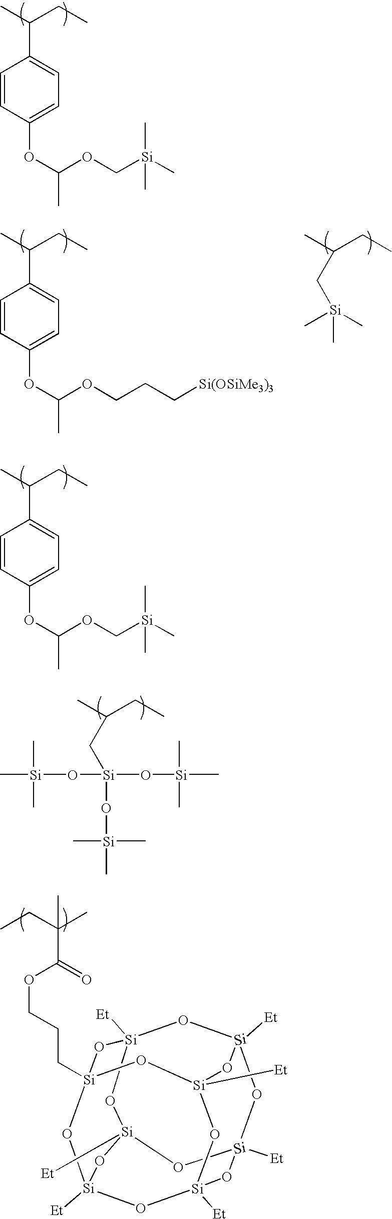

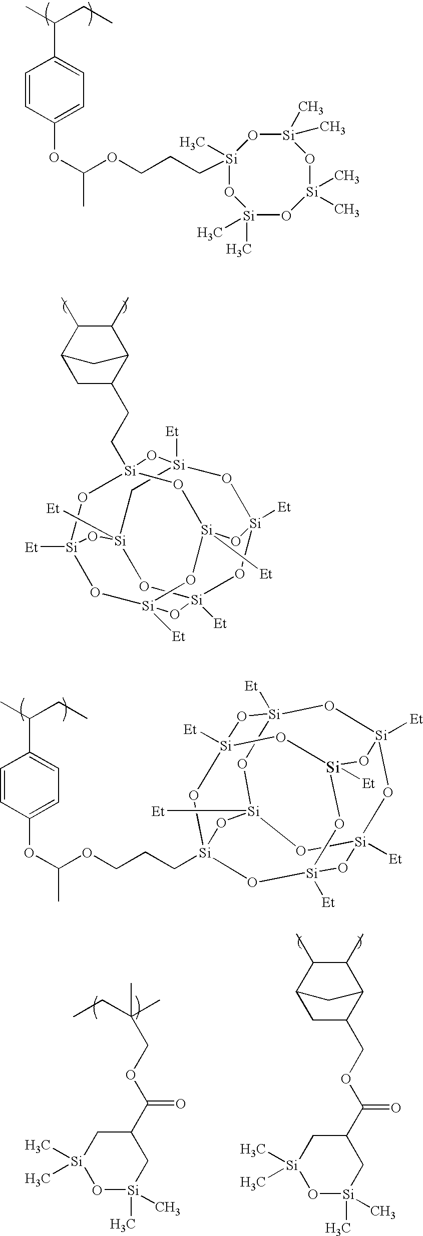

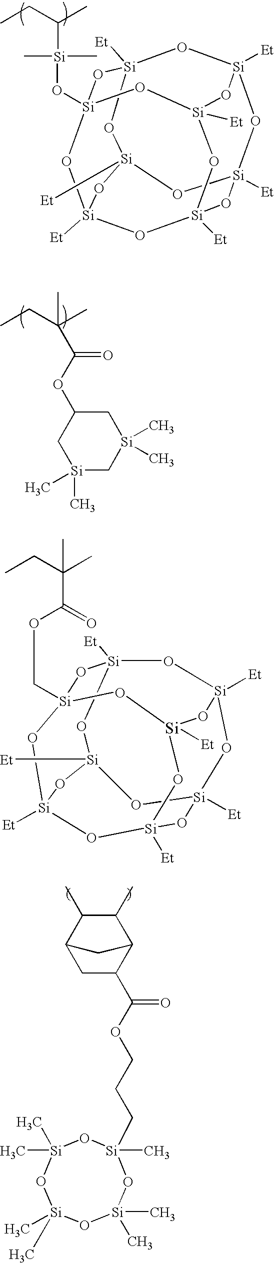

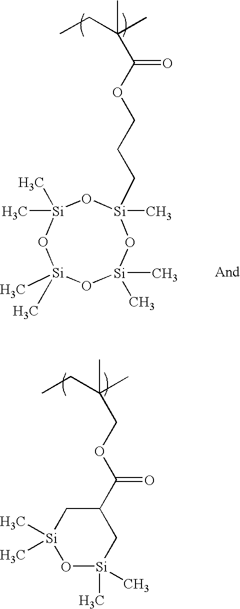

Additional examples of suitable monomers containing silicon include, but are not limited to, those found in U.S. Pat. Nos. 6,165,682, 5,985,524, 6,916,543 and 6,929,897, which are incorporated herein by reference.

In order to stabilize the image patterned in the photoresist film in the process of this invention, functional groups, referred to as anchor groups, must remain in the patterned film in order to react with the fixer group of the fixer solution. Typically, these functional groups are part of the polymer structure. The anchor groups in the photoresist film may be present in either reactive or protected form (i.e. an additional functional group or the blocked alkali solubilizing group). If the anchor groups are present in reactive form, the fixer solution can be applied directly, preferably dispersed in a suitable solvent, to the patterned film to fix or stabilize the image. If the anchor groups are present in protected form, they can be deprotected to generate the reactive form of the anchor group.

For example, if the protecting groups are acid-labile, the patterned film may be exposed to a blanket exposure of high energy radiation to remove the protecting groups from the film in the previously unexposed regions. These newly reactive anchor groups can then react with the fixer group to stabilize the image.

For the process of this invention, the blanket exposure may not be necessary for the invention to work. Along the line edge, there are polymer segments in which deblocking has occurred but not to sufficient degree for aqueous alkali solubility. These sites, possibly in combination with other unblocked reactive sites (depending on the polymer) may provide sufficient reactive sites for image fixing. The degree of image fixing for this invention is only that amount sufficient to produce an insolubility of the image in the casting solvent of the second photoresist coating. This is less than similar processes described in the prior art, which significantly swells the image.

Examples of anchor groups include, but are not limited to, the alkali solubilizing groups described above, carboxylic acid anhydrides, epoxides, isocyanates, thiophenols, or amino groups (which may be protected with an acid sensitive protecting group). Preferred anchor groups include carboxylic acids and carboxylic acid anhydrides. It is possible for many of these same functional groups to be employed in the fixer compound. However, the particular anchor group employed in the polymer is selected in combination with the fixer group in order to have a reactive pair combination.

Suitable monomers containing anchor groups include, but are not limited to the blocked alkali solubilizing monomers described above, maleic anhydride, cyclohexene dicarboxylic anhydride, norbornene dicarboxylic anhydride, itaconic anhydride, glycidyl acrylate, glycidyl methacrylate, hydroxyethyl methacrylate, 2,3-dihdroxypropyl acrylate and 2,3,-dihdroxypropyl methacrylate,

The polymer may also contain other non-reactive, non-acid sensitive monomers to help optimize optical and lithographic properties. Examples of other monomer types include, but are not limited to styrene monomers, acrylic and methacrylic ester monomers, vinyl ethers, vinyl esters, maleic mono- and di-esters, norbornene, and allyl esters.

Examples of suitable polymers include, but are not limited to those found in U.S. Pat. Nos. 6,165,682, 5,985,524, 6,916,543 and 6,929,897.

The polymers can be synthesized by conventional polymerization techniques, such as free radical polymization, or other techniques known to those skilled in the art.

The photosensitive composition will also contain a photoacid generating (PAG) compound. Typically, the PAG will be present in an amount of about 1 to 10% based on the weight of the polymer.

Any suitable photoacid generator compounds may be used in the radiation sensitive resist. The photoacid generator compounds are well known and include, for example, onium salts such as diazonium, sulfonium, sulfoxonium and iodonium salts, nitrobenzylsulfonate esters, oximesulfonates, imidosulfonates and disulfones. Suitable photoacid generator compounds are disclosed, for example, in U.S. Pat. Nos. 5,558,978, 5,468,589, 5,554,664 and 6,261,738, which are incorporated herein by reference. U.S. Pat. No. 6,261,738 discloses examples of suitable oximesulfonate PAGs. Other suitable photoacid generators are perfluoroalkyl sulfonyl methides and perfluoroalkyl sulfonyl imides as disclosed in U.S. Pat. No. 5,554,664.

Suitable examples of photoacid generators are phenacyl p-methylbenzenesulfonate, benzoin p-toluenesulfonate, α-(p-toluene-sulfonyloxy)methylbenzoin, 3-(p-toluenesulfonyloxy)-2-hydroxy-2-phenyl-1-phenylpropyl ether, N-(p-dodecylbenzenesulfonyloxy)-1,8-naphthalimide and N-(phenyl-sulfonyloxy)-1,8-napthalimide.

Examples of suitable onium salts included but are not limited to, triphenyl sulfonium methane sulfonate, triphenyl sulfonium trifluoromethanesulfonate, triphenyl sulfonium hexafluoropropanesulfonate, triphenyl sulfonium nonafluorobutanesulfonate, triphenyl sulfonium perfluorooctanesulfonate, triphenyl sulfonium phenyl sulfonate, triphenyl sulfonium 4-methyl phenyl sulfonate, triphenyl sulfonium 4-methoxyphenyl sulfonate, triphenyl sulfonium 4-chlorophenyl sulfonate, triphenyl sulfonium camphorsulfonate, 4-methylphenyl-diphenyl sulfonium trifluoromethanesulfonate, bis(4-methylphenyl)-phenyl sulfonium trifluoromethanesulfonate, tris-4-methylphenyl sulfonium trifluoromethanesulfonate, 4-tert-butylphenyl-diphenyl sulfonium trifluoromethanesulfonate, 4-methoxyphenyl-diphenyl sulfonium trifluoromethanesulfonate, mesityl-diphenyl sulfonium trifluoromethanesulfonate, 4-chlorophenyl-diphenyl sulfonium trifluoromethanesulfonate, bis(4-chlorophenyl)-phenyl sulfonium trifluoromethanesulfonate, tris(4-chlorophenyl) sulfonium trifluoromethanesulfonate, 4-methylphenyl-diphenyl sulfonium hexafluoropropanesulfonate, bis(4-methylphenyl)-phenyl sulfonium hexafluoropropanesulfonate, tris-4-methylphenyl sulfonium hexafluoropropanesulfonate, 4-tert-butylphenyl-diphenyl sulfonium hexafluoropropane sulfonate, 4-methoxyphenyl-diphenyl sulfonium hexafluoropropane sulfonate, mesityl-diphenyl sulfonium hexafluoropropane sulfonate, 4-chlorophenyl-diphenyl sulfonium hexafluoropropane sulfonate, bis(4-chlorophenyl)-phenyl sulfonium hexafluoropropane sulfonate, tris(4-chlorophenyl) sulfonium hexafluoropropane sulfonate, 4-methylphenyl-diphenyl sulfonium perfluorooctanesulfonate, bis(4-methylphenyl)-phenyl sulfonium perfluorooctanesulfonate, tris-4-methylphenyl sulfonium perfluoroocatanesulfonate, 4-tert-butylphenyl-diphenyl sulfonium perfluorooctane sulfonate, 4-methoxyphenyl-diphenyl sulfonium perfluorooctane sulfonate, mesityl-diphenyl sulfonium perfluorooctane sulfonate, 4-chlorophenyl-diphenyl sulfonium perfluorooctane sulfonate, bis(4-chlorophenyl)-phenyl sulfonium perfluorooctane sulfonate, tris(4-chlorophenyl)sulfonium perfluorooctane sulfonate, diphenyl iodonium hexafluoropropane sulfonate, diphenyl iodonium 4-methylphenyl sulfonate, bis(4-tert-butylphenyl)iodonium trifluoromethane sulfonate, bis(4-tert-butylphenyl)iodonium hexafluoromethane sulfonate, and bis(4-cyclohexylphenyl)iodonium trifluoromethane sulfonate.

Further examples of suitable photoacid generators for use in this invention are bis(p-toluenesulfonyl)diazomethane, methylsulfonyl p-toluenesulfonyldiazomethane, 1-cyclo-hexylsulfonyl-1-(1,1-dimethylethylsulfonyl)diazomethane, bis(1,1-dimethylethylsulfonyl)diazomethane, bis(1-methylethylsulfonyl)diazomethane, bis(cyclohexylsulfonyl)diazomethane, 1-p-toluenesulfonyl-1-cyclohexylcarbonyldiazomethane, 2-methyl-2-(p-toluenesulfonyl)propiophenone, 2-methanesulfonyl-2-methyl-(4-methylthiopropiophenone, 2,4-methyl-2-(p-toluenesulfonyl)pent-3-one, 1-diazo-1-methylsulfonyl-4-phenyl-2-butanone, 2-(cyclohexylcarbonyl-2-(p-toluenesulfonyl)propane, 1-cyclohexylsulfonyl-1 cyclohexylcarbonyldiazomethane, 1-diazo-1-cyclohexylsulfonyl-3,3-dimethyl-2-butanone, 1-diazo-1-(1,1-dimethylethylsulfonyl)-3,3-dimethyl-2-buta none, 1-acetyl-1-(1-methylethylsulfonyl)diazomethane, 1-diazo-1-(p-toluenesulfonyl)-3,3-dimethyl-2-butanone, 1-diazo-1-benzenesulfonyl-3,3-dimethyl-2-butanone, 1-diazo-1-(p-toluenesulfonyl)-3-methyl-2-butanone, cyclohexyl 2-d iazo-2-(p-toluenesulfonyl)acetate, tert-butyl 2-diazo-2-benzenesulfonylacetate, isopropyl-2-diazo-2-methanesulfonylacetate, cyclohexyl 2-diazo-2-benzenesulfonylacetate, tert-butyl 2 diazo-2-(p-toluenesulfonyl)acetate, 2-nitrobenzyl p-toluenesulfonate, 2,6-dinitrobenzyl p-toluenesulfonate, 2,4-dinitrobenzyl p-trifluoromethylbenzenesulfonate.

The photoacid generator compound is typically employed in the amounts of about 0.0001 to 20% by weight of polymer solids and more preferably about 1% to 10% by weight of polymer solids.

Suitable solvents for the radiation sensitive resists for the imaging layer include ketones, ethers and esters, such as methyl ethyl ketone, methyl isobutyl ketone, 2-heptanone, cyclopentanone, cyclohexanone, 2-methoxy-1-propylene acetate, 2-methoxyethanol, 2-ethoxyethanol, 2-ethoxyethyl acetate, 1-methoxy-2-propyl acetate, 1,2-dimethoxy ethane ethyl acetate, cellosolve acetate, propylene glycol monoethyl ether acetate, propylene glycol methyl ether acetate, methyl lactate, ethyl lactate, methyl pyruvate, ethyl pyruvate, ethyl 3-methoxypropionate, N-methyl-2-pyrrolidone, 1,4-dioxane, ethylene glycol monoisopropyl ether, diethylene glycol monoethyl ether, diethylene glycol monomethyl ether, diethylene glycol dimethyl ether, and the like. The solvents employed in the radiation sensitive resists for the imaging layer will be chosen with a view toward compatibility with the cycloolefin polymer in the Underlayer composition and the radiation sensitive resists for the imaging layer. For example, the choice of solvent for the radiation sensitive resist and the concentration thereof depends principally on the type of functionalities incorporated in the acid labile polymer, the photoacid generator, and the coating method. The solvent should be inert, should dissolve all the components in the resist, should not undergo any chemical reaction with the components and should be removable on drying after coating.

The photoresist composition may further comprise additives such as diffusion control agents, dyes, profile enhancement additives, surfactants, and silicon containing additives such as those described in U.S. Provisional patent application Ser. No. (Attorney's docket no. 335.8559USP, filed Feb. 8, 2007 entitled Photosensitive Compositions Employing Silicon-containing Additives), U.S. Pat. No. 6,210,856, and U.S. Patent Application Publication No. 2006/0063103, herein incorporated by reference.

The purpose of diffusion control agents is to prevent the photogenerated acid from diffusing too far and lower resolution. A secondary purpose is to scavenge protons present in the photoresist prior to being irradiated by the actinic radiation. The basis nature of the diffusion control agent prevents attack and cleavage of the acid labile groups by labile protons, thereby increasing the performance and stability of the resist. The percentage of diffusion control agent in the composition should be significantly lower than the photoacid generator or otherwise the photosensitivity becomes too low. The preferred range of the diffusion control agent, when present, is about 3% to 50% by weight of the photoacid generator compound. Nitrogenous bases are preferred. Suitable examples of diffusion control agents include, but are not limited to, cyclopropylamine, cyclobutylamine, cyclopentylamine, dicyclopentylamine, dicyclopentylmethylamine, dicyclopentylethylamine, cyclohexylamine, dimethylcyclohexylamine, dicyclohexylamine, dicyclohexylmethylamine, dicyclohexylethylamine, dicyclohexylbutylamine, cyclohexyl-t-butylamine, cycloheptylamine, cyclooctylamine, 1-adamantanamine, 1-dimethylaminoadamantane, 1-diethylaminoadamantane, 2-adamantanamine, 2-dimethylaminoadamantane, 2-aminonorbornene, and 3-noradamantanamine, 2-methylimidazole, tetramethyl ammonium hydroxide, tetrabutylammonium hydroxide, triisopropylamine, 4-dimethylaminopryidine, 4,4′-diaminodiphenyl ether, 2,4,5-triphenylimidazole, and 1,5-diazabicyclo[4.3.0]non-5-ene, and 1,8-diazabicyclo[5.4.0]undec-7-ene, guanidine, 1,1-dimethylguanidine, 1,1,3,3-tetramethylguanidine, 2-aminopyridine, 3-aminopyridine, 4-aminopyridine, 2-dimethylaminopyridine, 4-dimethylaminopyridine, 2-diethylaminopyridine, 2-(aminomethyl)pyridine, 2-amino-3-methylpyridine, 2-amino-4-methylpyridine, 2-amino-5-methylpyridine, 2-amino-6-methylpyridine, 3-aminoethylpyridine, 4-aminoethylpyridine, 3-aminopyrrolidine, piperazine, N-(2-aminoethyl)piperazine, N-(2-aminoethyl)piperidine, 4-amino-2,2,6,6-tetramethylpiperidine, 4-piperidinopiperidine, 2-iminopiperidine, 1-(2-aminoethyl)pyrrolidine, pyrazole, 3-amino-5-methylpyrazole, 5-amino-3-methyl-1-p-tolylpyrazole, pyrazine, 2-(aminomethyl)-5-methylpyrazine, pyrimidine, 2,4-diaminopyrimidine, 4,6-dihydroxypyrimidine, 2-pyrazoline, 3-pyrazoline, N-aminomorpholine, N-(2-aminoethyl)morpholine, trimethylimidazole, triphenylimidazole, and methyldiphenylimidazole

The photoresist composition may further comprise a surfactant. Suitable classes of surfactants include polysiloxanes, anionic, cationic, nonionic, and amphoteric surfactants. Nonionic surfactants which contain fluorine atoms and polysiloxanes are preferred. A person skilled in the art will be able to choose the appropriate surfactant and its concentration.

For the production of relief structures, the radiation-sensitive resist is imagewise exposed to actinic radiation. The term ‘imagewise’ exposure includes both exposure through a photomask containing a predetermined pattern, exposure by means of any suitable source of actinic radiation, such as for example, a computer controlled laser beam which is moved over the surface of the coated substrate, exposure by means of computer-controlled electron beams, and exposure by means of X-rays or UV rays, through a corresponding mask. The imagewise exposure generates acid in the exposed regions of the resist which catalyzes the cleavage of the acid labile groups resulting in a polymer which is aqueous soluble.

The exposure of the photosensitive composition may be done by “immersion lithography”. Immersion lithography refers to the use of an imaging apparatus in which the space between the final projection lens and the substrate containing the photosensitive composition is filled with an immersion liquid having a refractive index n larger than air. This type of apparatus is described in US Patent Application Publication No. 2005/0163629. Exposure using the immersion lithography technique is sometimes referred to as a “wet” exposure method while conventional exposures not using immersion lithography are referred to as “dry” exposure methods.

The immersion liquid may be any liquid that has a refractive index n>1, that is transparent at the wavelength of the exposing light and does not dissolve or chemically react with the photosensitive composition. The preferred immersion liquid for use with ArF excimer laser exposure systems comprises water. The water used should be substantially free of substances opaque to the actinic radiation and be free of impurities affecting the refractive index of water. Additives for the purpose of decreasing the surface tension of water, such as aliphatic alcohols having a refractive index of near or equal to that of water may be used. Examples of suitable alcohols include, but are not limited to, methyl alcohol, ethyl alcohol and isopropyl alcohol.

Optionally, prior to exposing the photosensitive composition coated substrate using immersion lithography, a protective coat may be applied directly on top of the photosensitive composition (topcoat) to prevent contacting the photosensitive composition with the immersion fluid. This topcoat, if used, should be substantially insoluble in the immersion fluid, be transparent to the actinic radiation, does not intermix with the photosensitive composition and can be uniformly coated. Examples of suitable topcoats are described in U.S. Patent Application Publication Nos. 2005/0277059, 2006/0189779, 2006/0008748 and 2006/0036005.

The process described above for the production of relief structures preferably includes, as a further process measure, heating of the coating between exposure and treatment with the developer. With the aid of this heat treatment, known as “post-exposure bake”, virtually complete reaction of the acid labile groups in the polymer with the acid generated by the exposure is achieved. The duration and temperature of this post-exposure bake can vary within broad limits and depend essentially on the functionalities of the polymer, the type of acid generator and on the concentration of these two components. The exposed resist is typically subjected to temperatures of about 50° C. to about 150° C. for a few seconds to a few minutes. The preferred post exposure bake is from about 80° C. to 130° C. for about 5 seconds to 180 seconds. Any suitable heating means may be employed. The preferred heating means is a hot plate.

After imagewise exposure and any heat treatment of the material, the exposed areas of the resist are removed by dissolution in an aqueous base developer to generate a relief structure. Examples of suitable bases include, but are not limited to, inorganic alkalis (e.g., potassium hydroxide, sodium hydroxide, ammonia water), primary amines (e.g., ethylamine, n-propylamine), secondary amines (e.g. diethylamine, di-n-propylamine), tertiary amines (e.g., triethylamine), alcoholamines (e.g. triethanolamine), quaternary ammonium salts (e.g., tetramethylammonium hydroxide, tetraethylammonium hydroxide), and mixtures thereof. The concentration of base employed will vary depending on the base solubility of the polymer employed and the specific base employed. The most preferred developers are those containing tetramethylammonium hydroxide (TMAH). Suitable concentrations of TMAH range from about 1 wt % to about 5 wt %.

The developer may contain a surfactant in a concentration from about 50 ppm to about 10,000 ppm. A preferred concentration, if surfactant is employed, is from about 100 ppm to about 5000 ppm. A more preferred concentration, if surfactant is employed, is from about 100 ppm to about 1000 ppm. Any surfactant type may be employable. Preferred surfactant types include nonionic, anionic, and amphoteric surfactants including their fluorinated versions. Nonionic surfactants, including fluorinated nonionic surfactants, are more preferred.

The developer may contain other additives, such as salts and antifoam agents.

Development of the photoresist can be carried out by means of immersion, spray, puddling, or other similar developing methods known to those skilled in the art at temperatures from about 10° C. to 40° C. for about 30 seconds to about 5 minutes with or without agitation.

After development, the relief pattern may be optionally rinsed with a rinse comprising de-ionized water or comprising de-ionized water containing one or more surfactants and dried by spinning, baking on a hot plate, in an oven, or other suitable means known to those skilled in the art. A preferred concentration of surfactant is from about 50 ppm to about 10000 ppm. A more preferred concentration of surfactant is from about 100 ppm to about 5000 ppm. A most preferred concentration of surfactant is from about 100 ppm to about 1000 ppm. Any surfactant type may be employable. Preferred surfactant types include nonionic, anionic, and amphoteric surfactants including their fluorinated versions. Nonionic surfactants, including fluorinated nonionic surfactants, are more preferred.

An optional reflow step may follow the development or drying of the resist image in order to shrink the size of the area from which the resist has been removed. The resist may heated to a temperature for a time that is specific to the resist employed in order to flow the resist in a controlled manner into the area from which the resist has been removed in order to obtain a predetermined feature size without significant distortion of the features. The reflow technique may lessen the difficulty of the lithographic patterning, and decrease line edge and line width roughness of the features. One trade-off for the technique is that the thickness of the resist is decreased, resulting in less protection for the underlying layer during a subsequent etch step.

The temperature of the reflow bake is dependent on the flow temperature of the resist employed and the bake technique and equipment employed. In a semiconductor track process, the typical resists employed in this process would require bake temperatures between about 130° C. and 180° C. Typical bake times would be from about 5 seconds to about 120 seconds.

Subsequently, the imaged bilayer stack is treated with a fixer solution to fix the relief image. Reaction between the anchor and the fixer groups change the solubility of the photoresist film thereby stabilizing the developed image. The fixer solution comprises a solvent, and a fixer compound which contains at least two functional groups reactive to the anchor group in the polymer of the photosensitive composition.

The fixer solvent system must have the following characteristics in order to be an effective vehicle for delivery of the fixer compound to the non-fixed resist image. It must be able to dissolve the fixer compound and it must not dissolve, deform or significantly swell the resist images. The selection of appropriate fixer solvent system will thus depend on the resist image solubility. Typical positive photoresists are soluble in moderately polar solvents such as alcohols, ketones, ethers and esters. Specific examples are propyleneglycol monomethyl ether (PGME), 2-heptanone, ethylene glycol monoethyl ether acetate (PGMEA), and diethylene glycol dimethyl ether. Such solvents either alone or blended with each other are obviously not appropriate for use in fixer solutions.

Solvent systems that are appropriate for fixer solutions are those that are either significantly less polar or significantly more hydrophilic than typical photoresist solvents. The solvent system can comprise one or more solvents that result in the desired polarity and dissolution power to dissolve the fixer compound without significantly perturbing the resist images. Furthermore, typical resist solvents are not precluded from use in the fixer solvent system as long as they are blended with one or more solvents whereby the resulting solvent system polarity and dissolving power meet the fixer solvent system criteria described above.

Examples of polar fixer solvent systems are water and blends of water miscible solvents with water. Such water miscible solvent include, but are not limited to alcohols such as methanol, ethanol, 1-propanol, 2-propanol, 1-butanol, and 2-butanol, and propyleneglycol monomethyl ether (PGME), and ethyl lactate are examples of appropriate blend partners with water, but in limited concentration to avoid dissolution of the resist image. Example of non-polar fixer solvents are alkanes such as C₅ to C₂₀ linear, branched or cyclic alkanes, including hexane, cyclohexane, octane, decane and dodecane. Such non-polar solvents can also be blended with alcohols (C₆-C₂₀) in order to enhance fixer compound solubility while ensuring resist image integrity. Examples of appropriate alcohols are 1-octanol, 1-decanol, 2-decanol and 1-dodecanol.

The solvent blend ratios will depend on the fixer solvent system criteria to maximize both fixer compound solubility and resist image integrity during the image fixing step. Thus, blend ratios can range from 0 to 100%.

The fixer compound contains at least two functional groups reactive to the anchor group in the polymer of the photosensitive composition. The functional groups can be the same or different. Examples of fixer compound functional groups include, but are not limited to, the alkali solubilizing groups described above, carboxylic acid anhydrides, epoxides, isocyanates, thiophenols, or amino groups. The fixer compounds can comprise an alkyl, cyclic, alicyclic and/or aromatic backbone and may be polymeric. Examples of polymeric fixer compounds, include but are not limited to, a 20 Mole % glycidyl acrylate and 80 mole % methylacrylate copolymer, and an isocyanato terminated polyethylene glycol. When a polymeric fixer is employed, low molecular weight oligomers are preferred. Preferred fixer compounds are polyamines such as diamines or triamines. Examples of polyamines are 1,4-pentanediamine, 1,6-hexanediamine, 1,5-pentanediamine, 1,4-cyclohexanediamine, 1,4-diaminobenzene, 1,4-bis-aminomethylbenzene, 1,3,5-tris-aminomethylbenzene

The identity of the functional groups on the fixer compound are chosen in combination with the choice of the anchor functional group in the polymer. When the polymer anchor group is an electrophilic moiety such as a cyclic anhydride, the fixer compound contains nucleophilic functionalities such as amino groups and thiol groups. When the polymer anchor group is a nucleophilic moiety such as an amine group, the fixer compound contains electrophilic functionality such as epoxy groups, anhydride groups, isocyanate groups, and thiocyanate groups. The preferred situation is where the polymer contains electrophilic anchor groups and the fixer compound contains nucleophilic groups.

Reaction of the nucleophilic groups with the electrophilic groups produces stable functional groups such as amides, thioesters, thioamides, ethers, or amines that will crosslink the film due to the multiple reaction sites on the anchor groups and the fixer compound. This changes the organic solvent solubility of the film.

For the purposes of this invention, it is important that the fixer compound does not contain silicon as a constituent atom. Introducing silicon into the fixer compound could result in expanded feature sizes after the underlayer etch, which would result in expanded feature sizes after etching of the underlying layers.

The concentration of the fixer compound in the fixer solution can range from 0.2 to 20 wt %, more preferably from 0.5 to 10 wt % and most preferably from 0.5 to 5 wt %.

The fixer solution can also optionally contain additives. One possible additive is a compound that will catalyze reaction of the fixer group with the anchor group of the polymer. Examples of such catalysts are non-nuclephilic tertiary amines such as triethylamine, trihexylamine, trioctylamine, tridodecylamine, triethoxyamine, N,N-dimethylbenzylamine, 1,5-diazabicyclo[4.3.0]non-5-ene (DBN), 1,4-diazabicyclo[2.2.2]octane (DABCO) or 1,8-diazabicyclo[5.4.0]undec-7-ene (DBU).

The catalyst can be added to the fixer solution in an amount ranging from 0.1 to 100 wt % relative to the fixer compound, more preferably from 0.2 to 50 wt % and most preferred from 0.5 to 5 wt %.

Surfactants are other optional additives that can be added to improve the coating and/or wetting ability of fixer solutions on the pattered wafer surfaces. Suitable surfactants are chosen based on solubility and activity in the fixer solvent. Nonionic surfactants are preferred in organic solvents. Nonionic surfactants without hydroxyl groups are preferred in organic solvents when the fixer group or the anchor group is an alcohol. Fluorinated nonionic surfactants are more preferred in organic solvents. In aqueous based fixer solvents, the surfactant may be nonionic, anionic, amphoteric, or cationic. ₃M™ Novec™ Fluorosurfactant FC-4430, 3M™ Novec™ Fluorosurfactant FC-4432, and 3M™ Novec™ Fluorosurfactant FC-4434 are examples of suitable non ionic fluorinated surfactants available from the 3M company. Troysol S-366, a nonionic siloxane type surfactant available from Troy Chemicals Industry, Inc.), DOWFAX 63N30, available from Dow Chemical, Megafac R08, a fluorinated type surfactant available from Dainippon Ink & Chemicals, Inc., the Surfynol® series of surfactants such as Surfynol 104®, Pluronic® P84, and Pluronic® 17R2, available from BASF, are further examples of suitable nonionic surfactants. ACCOSOFT® 501, available from Stepan Industries, QUARTAMIN 60W and SANISOL C, both available from Kao Corporation, are examples of suitable cationic surfactants. Lutensit-A-LBA, available from BASF, Stanfax 1012 and Stanfax 972, available from Para-Chem, are examples of suitable anionic surfactants. Tainolin CAPB, available from Jarchem Industries, Inc., and AMPHOSOL® DM, available from Stepan Industries, are examples of suitable amphoteric surfactants. Nonionic surfactants are preferred.

The concentration of surfactant, if employed in the fixer solution is from about 50 ppm to about 10,000 ppm. A preferred concentration, if surfactant is employed, is from about 100 ppm to about 5000 ppm. A more preferred concentration, if surfactant is employed, is from about 100 ppm to about 1000 ppm.

Polymers can be optionally added to the fixer solution as a coating matrix for the fixer compounds and any additional components such as catalyst, etc. Preferred polymers for the matrix must be soluble in the fixer solvents, nonreactive with the fixer components, have low reactivity with the anchor groups in the resist polymer, and have the ability to form uniform coatings. Thus, an image fixer solution containing such polymers can be spun over the developed image resulting in a thin film containing polymer, image fixer compound and other optional additives. This film encapsulates the developed images and places the fixer compounds uniformly in close proximity to the anchor groups. Examples of acceptable polymers include but are not limited to poly(ethylene oxide), poly(propylene oxide and polyvinyl alcohol. The polymer matrix is then removed by the rinse solution in a subsequent step.

The concentration of polymer in the fixer solution, if employed, is from about 0.5% to about 20%. A preferred concentration of polymer in the fixer solution, if employed, is from about 1% to about 15%. A more preferred concentration of polymer in the fixer solution, if employed, is from about 3% to about 10%. A most preferred concentration of polymer in the fixer solution, if employed, is from about 4% to about 7%.

The Image Fixing process can be carried out by applying the image fixing solution by means of immersion, spray, puddling, or other similar methods known to those skilled in the art at temperatures from about 10° C. to 40° C. A coating track is a preferred method for applying an image fixer onto a coated substrate. A material is typically dispensed with a stream or spray mode within the track. During the dispense process a static or dynamic coating method is typically utilized.

For a static dispense process, any desired amount of material can be dispensed onto the wafer, but typically 0.1 ml to 100 ml of the image fixer would be applied to the wafer while the wafer is still, forming a puddle on the wafer. After the dispense process the wafer would then be spun at a spin speeds ranging from 10 to 5000 rpm's for any desired duration, but typically between 1 second and 10 minutes. The spin step may consist of a multi-step process to uniformly spread the solution, and dry the film. This process can be carried out at any desired temperature, but typically in the range from about 10° C. to 40° C.

For a dynamic dispense process, any desired amount of material can be dispensed onto the wafer, but typically 0.1 mls to 100 mls of the image fixer would be applied to the wafer while the wafer is rotating. After the dispense process the wafer would then be spun at a spin speeds ranging from 10 to 5000 rpm's for any desired duration, but typically between 1 second and 10 minutes. This process can be carried out at any desired temperature, but typically in the range from about 10° C. to 40° C.

A temperature controlled coating chuck or a pre-plate can be used to further stabilize the wafer temperature.

Alternatively, the semiconductor substrate with an imaged resist layer can be removed from the coating track, to accomplish the image fixing process. In such a method the wafer can submersed in a bath solution containing the desired solution, at temperatures from about 10° C. to 40° C., and times ranging from about 5 seconds to 30 minutes.

Following the image fixing application step and any optional bake step immediately afterward, additional optional treatment steps may take place prior to a rinse step. Suitable treatment steps include, but are not limited to treatment with a polymer solution containing an acid, and a subsequent bake step carried out in the manner as described previously for the fixer solution and other bake steps.

The polymer solution containing an acid comprises a solvent, a polymer, and an acid. In another embodiment, the solution comprises a polymeric acid and a solvent. The solvent can be any number of solvents as long as these solvents are stable to acid and do not dissolve, deform or significantly swell the fixed resist images. The selection of appropriate solvent systems will thus depend on the fixed resist image solubility. Specific examples of rinse solvents can include, but are not limited to, typical resist casting solvents such as propyleneglycol monomethyl ether (PGME), 2-heptanone, ethylene glycol monoethyl ether acetate (PGMEA), diethylene glycol dimethyl ether. The solvent may also be water, alcohols, or mixtures of alcohol and water, or mixtures of either alcohol or water or both with other miscible solvents such as the resist casting solvents mentioned above.

The polymer employed in the polymer solution containing an acid should be acid stable and soluble in the solvent employed. Examples of suitable polymers include, but are not limited to poly(ethylene oxide) and poly(propylene oxide. In the embodiment employing a polymeric acid, suitable examples include, but are not limited to polyacrylic acid, polymethacrylic acid, and polyvinylsulfonic acid. The concentration of polymer in the polymer solution containing an acid is from about 0.5% to about 20%. A preferred concentration of polymer the polymer solution containing an acid is from about 1% to about 15%. A more preferred concentration of polymer in the polymer solution containing an acid is from about 3% to about 10%. A most preferred concentration of polymer the polymer solution containing an acid is from about 4% to about 7%.

Classes of acids that can be employed in the polymer solution containing an acid are linear, alkyl carboxylic acids, alkyl dicarboxylic acids, arylcarboxylic acids, alkyl sulfonic acids, arylsulfonic acids, perfluoroalkylsulfonic acids and inorganic acids. Examples of preferred acids are, acetic acid, propionic acid, benzoic acid, camphorsulfonic acid, decanesulfonic acid, para-toluenesulfonic acid and perfluorobutanesulfonic acid. The concentration of acid in the polymer solution containing an acid is typically between from about 0.5% to about 20%. A preferred acid concentration in the polymer solution containing an acid is from about 1% to about 15%. A more preferred acid concentration in the polymer solution containing an acid is from about 2% to about 10%. A most preferred acid concentration in the polymer solution containing an acid is from about 3% to about 7%.

The rinse process can utilize any number of solvents as long as these solvents do not dissolve, deform or significantly swell the fixed resist images. The selection of appropriate rinsing solvent systems will thus depend on the fixed resist image solubility. Specific examples of rinse solvents can include but are not limited to typical resist casting solvents or edge bead remover solvents such as propyleneglycol monomethyl ether (PGME), 2-heptanone, ethylene glycol monoethyl ether acetate (PGMEA), diethylene glycol dimethyl ether and ethyl lactate.

Alternatively, the rinse process can take place in the developer module of the semiconductor track system, in which case water would be a suitable rinsing solvent. Water, or water soluble solvents can be used alone, blended for use, or used consecutively such as a water rinse following by an isopropanol rinse. The rinse process can be carried out in a track or an immersion mode as described in the imaging fixing process.

Additionally, the rinse solution can contain additives. One such additive is an acid. An acid can be optionally added in the cases where basic compounds are used in the fixer solution in order to neutralize any residual unreacted fixer compounds or basic catalysts. Classes of acids that can be employed are linear, alkyl carboxylic acids, alkyl dicarboxylic acids, arylcarboxylic acids, alkyl sulfonic acids, arylsulfonic acids, perfluoroalkylsulfonic acids and inorganic acids. Examples of preferred acids are, acetic acid, propionic acid, benzoic acid, camphorsulfonic acid, decanesulfonic acid, para-toluenesulfonic acid and perfluorobutanesulfonic acid.

The concentration of acid, if employed in the rinse solution, is typically between from about 0.5% to about 20%. A preferred acid concentration, if employed in the rinse solution, is from about 1% to about 15%. A more preferred acid concentration, if employed in the rinse solution, is from about 1% to about 10%. A most preferred acid concentration, if employed in the rinse solution, is from about 1% to about 7%.

Alternatively, the rinse solution can contain a cation exchange compound. Suitable cation exchange compounds include, but are not limited to, quaternary ammonium hydroxides and other quaternary ammonium salts. Examples of quaternary ammonium salts include tetramethyl ammonium hydroxide, hydroxyethylammonium hydroxide, tetrahydroxyethylammonium hydroxide, tetramethylammonium acetate, tetramethylammonium propionate, tetramethylammonium lactate, tetraethyl ammonium formate, trimethylhydroxyethylammonium acetate, trimethylhydroxyethylammonium formate, trimethylhydroxyethylammonium lactate, tetramethylammonium citrate, and tetramethylammonium tartrate.

The concentration of cation exchange compound, if employed in the rinse solution, is typically between from about 0.5% to about 20%. A preferred cation exchange compound concentration, if employed in the rinse solution, is from about 1% to about 15%. A more preferred cation exchange compound concentration, if employed in the rinse solution, is from about 2% to about 10%. A most preferred cation exchange compound concentration, if employed in the rinse solution, is from about 3% to about 7%.

Surfactants are another optional additive that can be added to the rinse solution to improve its wetting ability to the patterned wafer surfaces. Preferred surfactants are compatible with the rinse solvents. Preferred surfactants for organic solvent based rinses are nonionic surfactants and polysiloxane type surfactants. The most preferred surfactants are fluorinated nonionic surfactants. Preferred surfactants for rinses containing water are nonionic surfactants.

The concentration of surfactant, if employed in the rinse solution is from about 50 ppm to about 10,000 ppm. A preferred concentration, if surfactant is employed in the rinse solution, is from about 100 ppm to about 5000 ppm. A more preferred concentration, if surfactant is employed in the rinse solution, is from about 100 ppm to about 1000 ppm.

The temperatures for the rinsing process can range from about 10° C. to 40° C., and times ranging from about 1 second to about 30 minutes.

The image fixing or rinse process can be followed by a drying step which can be accomplished by spin drying, air drying, or an optional bake step. For a spin drying process the wafer is spun at speeds ranging from about 10 to 5000 rpm's for any desired duration, but typically from about 1 second and 10 minutes. For an air drying process the solvent is allowed to evaporate under ambient conditions for about 1 second to 30 minutes. For the optional bake step, the wafer is baked at elevated temperatures from about 1 second to 30 minutes, at temperatures from about 17° C. to 250° C., using a track hotplate or a convection oven, or any other appropriate heating method.

Subsequent to the various post fixer treatment steps, a second coating of underlayer optionally may be applied and cured in a bake step as described previously. The underlayer may be the same or different as that applied initially in the process and may be of a different thickness.

A photosensitive composition is then coated in a second photosensitive composition coating step and optionally baked as described previously to produce a multilayer stack. This coating step may take place over the bilayer relief image or over the optional second underlayer coating. The photosensitive composition employed in the second photosensitive coating step may be the same or different from the first photosensitive composition. However, the second photosensitive composition must still comprise silicon. Preferably, the imagining layer has a thickness from about 50 nm to about 1000 nm. The thickness will be influence by whether the optional second underlayer coating is employed. A more preferred thickness is from about 100 nm to about 500 nm.

The multilayer stack is then imaged using one of the acceptable imagewise exposure methods described previously for the first photosensitive composition, which may be the same or different from the exposure employed for the first photosensitive composition. In this second exposure step, the placement of the second exposure pattern is offset from the first exposure by a predetermined amount.

The exposed multilayer stack is then optionally baked, developed in an aqueous base developer, rinsed and dried using methods described for the exposed first photosensitive composition. The details of the optional bake, development, rinse and dry processes may be the same or different than that employed for the first photosensitive composition. The patterned resist may then be subjected to the reflow bake as described above.

If desired, additional layers of photoresist or photoresist and underlayer may be applied and processed in the same manner as described above. In each layer, the placement of the exposure pattern is offset by a predetermined amount from the previous exposures.

In this double patterning process, the critical dimension (CD) can be impacted at two distinct steps in the process in such a way that the resist image CD grows in width. Firstly, the first patterned resist image can widen after the fixing step. This is believed to be as a result of mass uptake of the fixer molecule into the resist image surface during fixing. Secondly, the fixed image can grow after the second patterning step. Reasons for this growth are not well understood. The extent of CD growth at both steps can be affected by multiple processing variables, which include, but are not limited to fixer type, fixer concentrations, bake temperatures, rinses.

Additional steps are required to complete manufacture of devices. These steps may vary, depending on the particular device. However, most additional steps will begin with placing the imaged multilayer stack in a plasma-etching environment so that the Underlayer (or antireflective) film(s) will be removed in the area uncovered by the removal of resist. This operation is carried out by gas plasma etching using the imaged multilayer stack as a mask, thereby forming a micro pattern. Etch gas mixtures for plasma etching organic ARC materials or Underlayer films are disclosed in U.S. Pat. Nos. 5,773,199, 5,910,453, 6,039,888, 6,080,678, and 6,090,722. Of these, the '199 patent discloses a gas mixture of CHF₃+CF₄+O₂+Ar; the '453 patent discloses gas mixtures of N₂+He+O₂ or N₂+O₂ or N₂+He; the '888 discloses a gas mixture of O₂+CO; the '678 patent discloses a gas mixture of O₂+SO₂; and the '722 patent discloses a gas mixture of C₂F₆+Ar. The silicon incorporated in the radiation-sensitive resist forms silicon dioxide when exposed to a plasma with an etch gas comprising oxygen and protects the resist from being etched so that relief structures can be formed in the underlayer film and thereby uncovering portions of the underlying substrate. Nitrogen based etches (e.g. N₂/He or N₂/H₂) are thought to produce a silicon nitride or hydrogenated silicon nitride film

Subsequent to the plasma etch step, the now uncovered portions of the substrate are generally subjected to at least one further treatment step, which changes the substrate in areas not covered by the multilayer stack. Typically, this can be implantation of a dopant, deposition of another material on the substrate or etching of the substrate. This is usually followed by the removal of the multilayer stack from the substrate typically by a fluorine/oxygen plasma etch or N₂/H₂ plasma etch.

In another preferred embodiment, the present invention is a multiple exposure patterning process for manufacturing a semiconductor device using a multiple exposure patterning, comprising:
a) providing a coated semiconductor substrate with an antireflective coating,
b) applying in a first coating step, a first photosensitive composition over the coated semiconductor substrate to produce a bilayer stack,
c) exposing the first photosensitive composition in the bilayer stack in a imagewise manner to actinic radiation in a first exposure step to produce a first pattern,
d) developing the exposed first photosensitive composition in an aqueous base developer to produce an imaged bilayer stack containing a relief image,
e) rinsing the imaged bilayer stack containing the relief image with an aqueous liquid optionally containing a surfactant,
f) applying a fixer solution to the imaged bilayer stack to stabilize (fix) the relief image,
g) applying an optional bake step,
h) rinsing the imaged bilayer stack containing the stabilized image with a liquid optionally containing a surfactant,
i) applying a second optional bake step,
j) applying in a second coating step a second photosensitive composition onto the imaged bilayer stack to produce a multilayer stack,
k) exposing the second photosensitive composition in the multilayer stack in an imagewise manner to actinic radiation in a second exposure step to produce a second pattern in which the placement of the second exposure pattern is offset from the first exposure pattern by a predetermined amount,
l) developing the exposed second photosensitive composition in an aqueous base developer to produce an imaged multilayer stack containing a second relief image, and
m) rinsing the imaged multilayer stack containing the second relief image with an aqueous liquid optionally containing a surfactant;
   wherein the first and second photosensitive compositions each comprise a photoacid generator and a substantially aqueous base insoluble polymer not containing silicon atoms whose aqueous base solubility increases upon treatment with acid and further comprises an anchor group, and the fixer solution comprises a polyfunctional fixer compound which is reactive with the anchor group, but does not contain silicon and wherein the semiconductor substrate stays within a lithographic cell from at least the first coating step until at least after the final exposure.

This embodiment is similar in many respects to the previous embodiment. Key differences concerning the use of a bottom anti-reflective coating instead of an underlay and the use of a non-silicon containing polymer in the photoresist instead of a silicon containing polymer, and the ramifications of those differences.

The use of bottom antireflective coatings (BARCs) with photoresists is well known to those in the art and can be found, for example in U.S. Pat. Nos. 6,670,425, 5,919,599, 5,234,990, 7,026,101, 6,887,648, 6,653,049, 6,602,652, 5,733,714, 6,803,168, 6,274,295 and 6,187,506, herein incorporated by reference. Examples of organic BARC suitable for 248 nm lithography include, but are not limited to, ARC®82A, ARC®66, DUV32, DUV44, DUV44P, DUV54 and DUV64, all available from Brewer Science Inc. Typical single layer 193 nm BARCs include ArF-1C5D, ArF 1C6B, ArF 2C6B, ArF 38, ArF 45 (available from AZ), ARC 29A, and ARC 28 available from Brewer Science), and AR 19 (available from Rohm and Haas).

In composition, BARCs have similarities to underlayers. However, BARCs are designed with different optical properties (e.g. higher absorbance) in order to control reflections with thinner films. In addition, BARCs are designed to be quickly removed by an oxidative etch process in order to not etch away very much of the non-silicon containing imaging resist coated above it. In contrast, the underlayers are designed for use in thicker films, have lower absorbance, and are designed to resist substrate etch processes, a requirement assigned to the non silicon containing resist in a imaging layer/BARC system.

The B.A.R.C. thickness may be any thickness suitable for the lithographic application. A preferred B.A.R.C. film thickness range is from about 60 nm to about 150 nm for the case where only one B.A.R.C. layer is employed. The more preferred B.A.R.C. film thickness is from about 70 nm to about 100 nm when only one B.A.R.C. layer is employed.

The substrate may also be optionally coated with a multiple layer BARC. The advent of High NA exposures tools (NA>1), has introduced a new set of challenges that need to be contended with. Namely minimizing reflected light over a wide range of incident angles introduced with high NA systems, which are achievable with immersion exposure. Single (layer) BARC systems are not effective in minimizing reflectivity with high NA exposure tools as described in SPIE Proceedings, Vol. 6153, p. 56 (2006), and SPIE Proceedings, Vol. 5753, p. 49 (2005). In order to minimize the substrate reflected light over wide ranges of incident angles, a multiple layer BARC scheme is useful. The optical properties and thickness of two BARC layers can be optimized to control reflectivity to <1% as described in SPIE Proceedings, Vol. 5753, p. 49. In addition the etch properties of the BARCs are adjusted to achieve high etch rates in a dry etch plasma to facilitate efficient pattern transfer into the dual BARC system. The use of multilayer B.A.R.C.s and their general characteristics are described in Advances in Resist Technology and Processing, volume 5753 pp 417-435 (2005), volume 6519 pp 651928-1 to 651928-10, 651929-1 to 651929-10, and 65192A-1 to 65192A-8 (2007).

The thickness of the first applied bottom anti-reflective coating (lower BARC) will be thinner than in the single B.A.R.C. situation, in order to maintain a similar total BARC thickness to prevent excess etching of the photoresist layer in the etch step(s) to remove BARC (s) in the imaged areas. With a two layer BARC system, the film thickness employed for the lower BARC is from about 10 nm to about 80 nm. A preferred BARC thickness for the lower BARC is from about 20 nm to about 60 nm. A more preferred film thickness for the lower BARC is from about 20 nm to about 50 nm.

The thickness of the second applied bottom anti-reflective coating (upper BARC) will also be thinner, in order to maintain a similar total BARC thickness to prevent excess etching of the photoresist layer in the etch step(s) to remove BARC s) in the imaged areas. With a two layer BARC system, the film thickness employed for the upper BARC is from about 20 nm to about 100 nm. A preferred BARC thickness for the upper BARC is from about 20 nm to about 80 nm. A more preferred film thickness for the upper BARC is from about 20 nm to about 60 nm.

The photoresist film thickness in the photoresist film/BARC stack is optimized for lithographic performance and the need to provide plasma etch resistance for both the image transfer into the BARC and subsequently into the substrate. Preferably the photoresist film has a thickness from about 50 nm to about 500 nm. A more preferred photoresist film thickness range is from about 80 nm to about 250 nm. The most preferred photoresist film thickness is from 100 nm to 170 nm.

The non-silicon containing polymer employed may be similar to the silicon containing polymers described in the previous embodiment regarding the anchor groups and acid sensitive groups. However, the design places more emphasis on having substrate plasma etch resistance moieties in the polymer. Examples of suitable polymers include, but are not limited to polymers described in U.S. Pat. No. 7,258,963, U.S. Pat. No. 7,122,291, U.S. Pat. No. 7,084,227, U.S. Pat. No. 7,033,740, U.S. Pat. No. 7,022,455, U.S. Pat. No. 6,365,322, U.S. Pat. No. 6,410,620, U.S. Pat. No. 556,734, U.S. Pat. No. 5,492,793, U.S. Pat. No. 5,679,495, U.S. Pat. No. 5,670,299, and U.S. Pat. No. 7,217,496.

### EXPERIMENTAL

### Fixer Formulation Example 1

### Image Fixing Solution

An image fixing solution was prepared consisting of 4 parts by weight of hexamethylenediamine, 69 parts by weight of decane, and 27 parts by weight of 2-octanol. The components were mixed in an amber glass bottle, which was rolled for 24 hours during the mixing process.

### Lithographic Process Example 1

TIS 248UL-01-50 underlayer available from FUJIFILM Electronic Materials U.S.A., Inc., was applied to a 200 mm silicon wafer and spun coated using a DNS 80B coating track, to achieve a film thickness on 500 nm after baking for 200° C. for 70 seconds, using an inline bake plate configured within the DNS 80B. TIS 248IL-01-23 imaging layer photoresist, a chemically amplified, silicon and anhydride containing resist available from FUJIFILM Electronic Materials U.S.A., Inc., was applied onto the underlayer, using the DNS 80B coating track, to achieve a film thickness of 239 nm after baking for 125° C. for 90 seconds. The wafer, having a film stack of underlayer and photoresist, was irradiated through a binary mask containing line space patterns, with a focus exposure matrix using a Canon EX6 248 nm stepper. The stepper illumination settings included a numerical aperture of 0.65, with an annular setting having an outer sigma of 0.80 and an inner sigma of 0.50.

Following the exposure step the wafer was baked at 115° C. for 90 seconds and then developed using OPD 262 developer, a 0.26N TMAH based solution available from FUJIFILM Electronic Materials U.S.A., Inc. The developer was dispensed for 10 seconds, followed by a 55 second static puddle development, a DI water rinse and a spin dry step. A series of line space patterns were formed.

An image fixing solution described in Fixer Formulation Example 1 was applied to the imaged wafer, which was then spun at 2 krpm. A DI water rinse step for 7 seconds followed. The wafer was then spun dried at 4 krpm using the DNS 80B track.

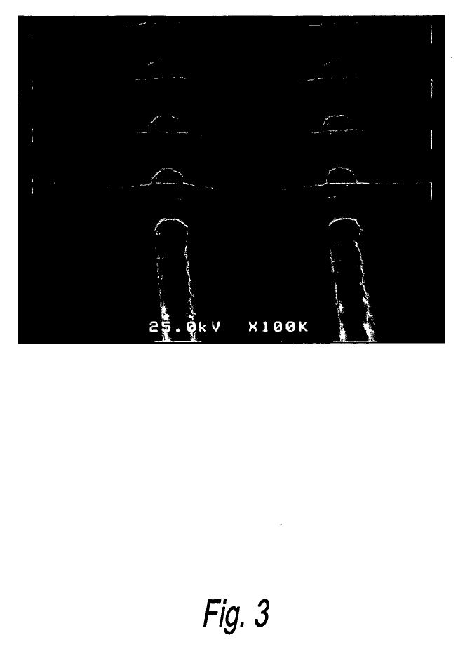

A second coat of TIS 248IL-01-23 imaging layer photoresist applied to the fixed image layer on the wafer, using the DNS 80B coating track. The multilayer film was processed using the bake, exposure, bake, develop, rinse, and dry steps employed above for processing the first photosensitive composition, with the exception that the binary mask was rotated 90°. A double patterned image was formed, with the second set of lines perpendicular to and crossing over the first set of patterned lines without significant intermixing of the imaging layers as shown below in FIG. 3. This demonstrates the critical aspect of the process of the invention, so that the process of the invention can suitably be carried out with appropriate overlay and alignment capabilities on the exposure tool.

### General Lithographic Procedure 1

Silicon wafers were first spin-coated with an underlayer film (UL), TIS193UL-52-50 (a product of FujiFilm Microelectronics, Inc.), and baked for 90 seconds at 200° C. to yield a UL thickness of 160 nm. TIS193UL-52-50 is of the type described in U.S. Pat. No. 6,916,543. An imaging layer (IL), TIS193IL-PH (B50), (also a product of FujiFilm Microelectronics, Inc.) was then applied by spin-coating over the underlayer and was post-apply baked (PAB) for 90 seconds at 135° C. resulting in an IL film thickness of 130 nm. TIS193IL-B50 is a chemically amplified photosentitive imaging layer (IL) that comprises a polymer with incorporated anhydride functionalities and silicon containing moieties. The IL was then exposed through a 6% attenuated phase-shift photomask containing line and space patterns on an ASML PAS 5500/1100 (ArF, 193 nm eximer laser beam) with a numerical aperture of 0.75 and C-Quad Illumination (0.92 σₒ/0.72 σᵢ). Die were printed with an incremental change of focus and exposure dose typical of a focus/exposure matrix. Wafers were subjected to a post-exposure bake (PEB) at 100° C. for 90 seconds, and IL patterns were developed via a puddle process for 60 seconds with OPD-262. A 30 seconds deionized (DI) water rinse and spin-dry step followed development. The typical target critical dimension (CD) formed using this procedure was between 80 nm and 160 nm lines and spaces with a duty cycle of 1:1.

### General Lithographic Procedure 2

General Lithographic Procedure 2 is the same as General Lithographic Procedure 1 with the exceptions that annular illumination (0.85 σₒ/0.55 σᵢ) was employed using a fixed focus and exposure (17-20 mJ/cm² depending on the particular experiment.) The typical target critical dimension (CD) formed using this procedure was either 80 nanometer (nm) lines and 160 nm spaces (semi-dense features) or 80 nm lines and 800 nm spaces (isolated features).

### Fixing Procedure

Subsequent to forming relief patterns using Lithographic Procedure 1 or 2, a fixing step was performed for the purpose of rendering previously formed images insoluble to photoresist solutions and organic casting solvent(s) contained therein. The fixing process employed either a Puddle Process (PP) or a Spin-Coat Process (SCP).

### Puddle Process (PP)

Within the developer module of the coater and developer track, approximately 70 milliliters of fixer solution was slowly poured manually onto a patterned wafer forming a puddle reaching to the edge of the wafer in a similar manner to a resist developer puddle formed during a typical development step. After 60 seconds the fixer puddle was spun off and the resulting wafer surface was either rinsed with DI water for 30 seconds before being subjected to a post-fix bake step (rinse before bake: RBB), or was first subjected to a post-fix bake step then rinsed with DI water for 30 seconds (bake before rinse: BBR). Post-fix bake temperatures and durations varied as specified in the specific experiment.

### Spin Coat Process (SCP)

Within the coater module of the coater and developer track, approximately 2 milliliters of fixer solution was dispensed manually by pipette onto a patterned wafer which was then spun at approximately 2000 RPM for 30 seconds forming a fixer film. The wafer was then subjected to a post-fix bake step of various temperatures and durations followed by a 30 seconds DI water rinse.

### General Fixer Formulation Procedure

Fixer components as described in the examples were mixed in an amber bottle and rolled until all components were dissolved.

TABLE 1
Fixer Formulation Examples 2-26

| Fixer | Crosslinker/ | Quantity | | Quantity | | Quantity |
|---|---|---|---|---|---|---|
| Formulation | Fixing Agent | grams | Solvent 1 | grams | Solvent 2 | grams |
| 2 | Hexamethylene- | 0.99 | Decane | 16.4 | 2- | 6.5 |
| | diamine | | | | Octanol | |
| 3 | Hexamethylenediamine | 0.62 | Decane | 3.6 | 2- | 10.8 |
| | | | | | Octanol | |
| 4 | Hexamethylenediamine | 0.62 | Decane | 7.2 | 2- | 7.2 |
| | | | | | Octanol | |
| 5 | Hexamethylenediamine | 0.62 | Decane | 10.3 | 2- | 4.1 |
| | | | | | Octanol | |
| 6 | Hexamethylenediamine | 0.62 | Decane | 12.9 | 2- | 1.4 |
| | | | | | Octanol | |
| 7 | Hexamethylenediamine | 0.62 | DI Water | 3.6 | Ethyl | 10.8 |
| | | | | | Lactate | |
| 8 | Hexamethylenediamine | 0.62 | DI Water | 7.2 | Ethyl | 7.2 |
| | | | | | Lactate | |
| 9 | Hexamethylenediamine | 0.62 | DI Water | 10.8 | Ethyl | 3.6 |
| | | | | | Lactate | |
| 10 | Hexamethylenediamine | 0.62 | DI Water | 12.9 | Ethyl | 1.4 |
| | | | | | Lactate | |
| 11 | Hexamethylenediamine | 0.62 | DI Water | 14.4 | | |
| 12 | Hexamethylenediamine | 0.25 | DI Water | 49.8 | | |
| 13 | Hexamethylenediamine | 0.62 | DI Water | 13.6 | | |
| 14 | Hexamethylenediamine | 0.01 | DI Water | 18.0 | | |
| 15 | Hexamethylenediamine | 0.05 | DI Water | 18.0 | | |
| 16 | Hexamethylenediamine | 0.10 | DI Water | 18.0 | | |
| 17 | Hexamethylenediamine | 0.25 | DI Water | 18.0 | | |
| 18 | Hexamethylenediamine | 0.50 | DI Water | 18.0 | | |
| 19 | Hexamethylenediamine | 0.25 | DI Water | 47.3 | | |
| 20 | Hexamethylenediamine | 0.50 | DI Water | 47.0 | | |
| 21 | Hexamethylenediamine | 1.00 | DI Water | 46.5 | | |
| 22 | Hexamethylenediamine | 28.6 | DI Water | 1771.4 | | |
| | (70% | | | | | |
| | aqueous | | | | | |
| | solution) | | | | | |
| 23 | Hexamethylenediamine | 57.1 | DI Water | 1742.9 | | |
| | (70% | | | | | |
| | aqueous | | | | | |
| | solution) | | | | | |
| 24 | Hexamethylenediamine | 85.7 | DI Water | 1714.3 | | |
| | (70% | | | | | |
| | aqueous | | | | | |
| | solution) | | | | | |
| 25 | Hexamethylenediamine | 114.3 | DI Water | 1685.7 | | |
| | (70% | | | | | |
| | aqueous | | | | | |
| | solution) | | | | | |
| 26 | Hexamethylenediamine | 1.79 | DI Water | 223.2 | | |
| | (70% | | | | | |
| | aqueous | | | | | |
| | solution) | | | | | |

| | | | | | Total |
|---|---|---|---|---|---|
| Fixer | | Quantity | | Quantity | Quantity |
| Formulation | Polymer | grams | Surfactant | grams | grams |
| 2 | | | | | 24.0 |
| 3 | | | | | 15.0 |
| 4 | | | | | 15.0 |
| 5 | | | | | 15.0 |
| 6 | | | | | 15.0 |
| 7 | | | | | 15.0 |
| 8 | | | | | 15.0 |
| 9 | | | | | 15.0 |
| 10 | | | | | 15.0 |
| 11 | | | | | 15.0 |
| 12 | | | | | 50.0 |
| 13 | | | Surfynol | 0.75 | 15.0 |
| | | | 465 (1% | | |
| | | | aqueous | | |
| | | | solution) | | |
| 14 | Poly(ethylene | 0.99 | Surfynol | 1.0 | 20.0 |
| | glycol) | | 465 (1% | | |
| | | | aqueous | | |
| | | | solution) | | |
| 15 | Poly(ethylene | 0.95 | Surfynol | 1.0 | 20.0 |
| | glycol) | | 465 (1% | | |
| | | | aqueous | | |
| | | | solution) | | |
| 16 | Poly(ethylene | 0.90 | Surfynol | 1.0 | 20.0 |
| | glycol) | | 465 (1% | | |
| | | | aqueous | | |
| | | | solution) | | |
| 17 | Poly(ethylene | 0.75 | Surfynol | 1.0 | 20.0 |
| | glycol) | | 465 (1% | | |
| | | | aqueous | | |
| | | | solution) | | |
| 18 | Poly(ethylene | 0.50 | Surfynol | 1.0 | 20.0 |
| | glycol) | | 465 (1% | | |
| | | | aqueous | | |
| | | | solution) | | |
| 19 | | | Pluronic | 2.5 | 50.0 |
| | | | P84 (1% | | |
| | | | aqueous | | |
| | | | solution) | | |
| 20 | | | Pluronic | 2.5 | 50.0 |
| | | | P84 (1% | | |
| | | | aqueous | | |
| | | | solution) | | |
| 21 | | | Pluronic | 2.5 | 50.0 |
| | | | P84 (1% | | |
| | | | aqueous | | |
| | | | solution) | | |
| 22 | | | Pluronic | 200.0 | 2000.0 |
| | | | P84 (1% | | |
| | | | aqueous | | |
| | | | solution) | | |
| 23 | | | Pluronic | 200.0 | 2000.0 |
| | | | P84 (1% | | |
| | | | aqueous | | |
| | | | solution) | | |
| 24 | | | Pluronic | 200.0 | 2000.0 |
| | | | P84 (1% | | |
| | | | aqueous | | |
| | | | solution) | | |
| 25 | | | Pluronic | 200.0 | 2000.0 |
| | | | P84 (1% | | |
| | | | aqueous | | |
| | | | solution) | | |
| 26 | | | Pluronic | 25.0 | 250.0 |
| | | | P84 (1% | | |
| | | | aqueous | | |
| | | | solution) | | |

TABLE 2
Fixer Formulation Examples 27-44

| | | | | | | | | | Total |
|---|---|---|---|---|---|---|---|---|---|
| Fixer | Crosslinker/Fixing | Quantity, | | | | | | | Quantity, |
| Formulation | Agent | g | Solvent 1 | Quantity, g | Polymer | Quantity, g | Surfactant | Quantity, g | g. |
| 27 | Hexamethylene | 0.25 | DI Water | 17.0 | Poly(ethylene | 0.73 | Pluronic P84 | 2.0 | 20.0 |
| | diamine | | | | glycol) | | (1% aqueous | | |
| | | | | | | | solution) | | |
| 28 | Hexamethylene | 0.50 | DI Water | 17.0 | Poly(ethylene | 0.48 | Pluronic P84 | 2.0 | 20.0 |
| | diamine | | | | glycol) | | (1% aqueous | | |
| | | | | | | | solution) | | |
| 29 | Hexamethylene | 0.75 | DI Water | 17.0 | Poly(ethylene | 0.23 | Pluronic P84 | 2.0 | 20.0 |
| | diamine | | | | glycol) | | (1% aqueous | | |
| | | | | | | | solution) | | |
| 30 | Hexamethylene | 50.0 | DI Water | 580.0 | | | Pluronic P84 | 70.0 | 700.0 |
| | diamine (70% | | | | | | (1% aqueous | | |
| | aqueous | | | | | | solution) | | |
| | solution) | | | | | | | | |
| 31 | Hexamethylene | 75.0 | DI Water | 555.0 | | | Pluronic P84 | 70.0 | 700.0 |
| | diamine (70% | | | | | | (1% aqueous | | |
| | aqueous | | | | | | solution) | | |
| | solution) | | | | | | | | |
| 32 | Hexamethylene | 0.09 | DI Water | 17.0 | Poly(ethylene | 0.90 | Pluronic P84 | 2.0 | 20.0 |
| | diamine | | | | glycol) | | (1% aqueous | | |
| | | | | | | | solution) | | |
| 33 | Hexamethylene | 0.06 | DI Water | 17.0 | Poly(ethylene | 0.93 | Pluronic P84 | 2.0 | 20.0 |
| | diamine | | | | glycol) | | (1% aqueous | | |
| | | | | | | | solution) | | |
| 34 | Hexamethylene | 0.02 | DI Water | 17.0 | Poly(ethylene | 0.96 | Pluronic P84 | 2.0 | 20.0 |
| | diamine | | | | glycol) | | (1% aqueous | | |
| | | | | | | | solution) | | |
| 35 | Hexamethylene | 2.9 | DI Water | 357.1 | | | Pluronic P84 | 40.0 | 400.0 |
| | diamine (70% | | | | | | (1% aqueous | | |
| | aqueous | | | | | | solution) | | |
| | solution) | | | | | | | | |
| 36 | Hexamethylene | 2.0 | DI Water | 358.0 | | | Pluronic P84 | 40.0 | 400.0 |
| | diamine (70% | | | | | | (1% aqueous | | |
| | aqueous | | | | | | solution) | | |
| | solution) | | | | | | | | |
| 37 | Hexamethylene | 1.1 | DI Water | 358.9 | | | Pluronic P84 | 40.0 | 400.0 |
| | diamine (70% | | | | | | (1% aqueous | | |
| | aqueous | | | | | | solution) | | |
| | solution) | | | | | | | | |
| 38 | Hexamethylene | 0.3 | DI Water | 359.7 | | | Pluronic P84 | 40.0 | 400.0 |
| | diamine (70% | | | | | | (1% aqueous | | |
| | aqueous | | | | | | solution) | | |
| | solution) | | | | | | | | |
| 39 | 4,4- | 0.2 | Decane | 19.8 | | | | | 20.0 |
| | Methylenebis(2- | | | | | | | | |
| | methylcyclo- | | | | | | | | |
| | hexylamine) | | | | | | | | |
| 40 | 4,4- | 1.0 | Decane | 19.0 | | | | | 20.0 |
| | Methylenebis(2- | | | | | | | | |
| | methylcyclo- | | | | | | | | |
| | hexylamine) | | | | | | | | |
| 41 | 4,4- | 2.0 | Decane | 18.0 | | | | | 20.0 |
| | Methylenebis(2- | | | | | | | | |
| | methylcyclo- | | | | | | | | |
| | hexylamine) | | | | | | | | |
| 42 | Hexamethylene | 7.1 | DI Water | 442.9 | | | Pluronic P84 | 50.0 | 500.0 |
| | diamine (70% | | | | | | (1% aqueous | | |
| | aqueous | | | | | | solution) | | |
| | solution) | | | | | | | | |
| 43 | Hexamethylene | 0.36 | DI Water | 18.9 | Poly(ethyleneglycol) | 0.75 | | | 20.0 |
| | diamine (70% | | | | dimethyl | | | | |
| | aqueous | | | | ether | | | | |
| | solution) | | | | | | | | |
| 44 | Hexamethylene | 0.14 | DI Water | 19.0 | Poly(ethyleneglycol) | 0.90 | | | 20.0 |
| | diamine (70% | | | | dimethyl | | | | |
| | aqueous | | | | ether | | | | |
| | solution) | | | | | | | | |

TABLE 3
Fixer Formulation Examples 45-62

| Fixer | Crosslinker/Fixing | | | | | | |
|---|---|---|---|---|---|---|---|
| Formulation | Agent | Quantity, g | Solvent 1 | Quantity, g | Solvent 2 | Quantity, g | Polymer |
| 44 | Hexamethylenediamine | 0.14 | DI Water | 19.0 | | | Poly(ethyleneglycol) |
| | (70% aqueous | | | | | | dimethyl |
| | solution) | | | | | | ether |
| 45 | Hexamethylenediamine | 0.36 | DI Water | 18.9 | | | Poly(ethyleneglycol) |
| | (70% aqueous | | | | | | dimethyl |
| | solution) | | | | | | ether |
| 46 | Hexamethylenediamine | 0.14 | DI Water | 19.0 | | | Poly(ethyleneglycol) |
| | (70% aqueous | | | | | | dimethyl |
| | solution) | | | | | | ether |
| 47 | Ethylenediamine | 7.0 | DI Water | 623.0 | | | |
| 48 | Ethylenediamine | 3.0 | DI Water | 267.0 | | | |
| 49 | Ethylenediamine | 0.34 | DI Water | 19.0 | | | Poly(ethyleneglycol) |
| | | | | | | | dimethyl |
| | | | | | | | ether |
| 50 | 4,4- | 0.25 | DI Water | 28.9 | | | Poly(ethyleneglycol) |
| | Diaminobibenzyl | | | | | | dimethyl |
| | | | | | | | ether |
| 51 | 4,4- | 0.25 | DI Water | 19.0 | | | Poly(ethyleneglycol) |
| | Diaminobibenzyl | | | | | | dimethyl |
| | | | | | | | ether |
| 52 | Ethylenediamine | 7.8 | DI Water | 694.2 | | | |
| 53 | Ethylenediamine | 1.5 | DI Water | 133.5 | | | |
| 54 | Ethylenediamine | 1.5 | DI Water | 100.1 | IPA | 33.4 | |
| 55 | Ethylenediamine | 1.5 | DI Water | 66.8 | IPA | 66.8 | |
| 56 | Ethylenediamine | 1.5 | DI Water | 33.4 | IPA | 100.1 | |
| 57 | Ethylenediamine | 1.5 | IPA | 133.5 | | | |
| 58 | Ethylenediamine | 0.28 | DI Water | 17.0 | | | Poly(ethylene |
| | | | | | | | glycol) |
| 59 | Ethylenediamine | 0.17 | DI Water | 17.0 | | | Poly(ethylene |
| | | | | | | | glycol) |
| 60 | Ethylenediamine | 0.10 | DI Water | 17.0 | | | Poly(ethylene |
| | | | | | | | glycol) |
| 61 | Ethylenediamine | 8.5 | DI Water | 756.5 | | | |
| 62 | Ethylenediamine | 18.0 | DI Water | 1764.0 | | | |

| | | | | | | Total |
|---|---|---|---|---|---|---|
| Fixer | | | | | | Quantity, |
| Formulation | Quantity, g | Surfactant | Quantity, g | Additive | Quantity, g | g. |
| 44 | 0.90 | | | | | 20.0 |
| 45 | 0.06 | | | DBU | 0.69 | 20.0 |
| 46 | 0.63 | | | DBU | 0.28 | 20.0 |
| 47 | | Pluronic P84 | 70.0 | | | 700.0 |
| | | (1% aqueous | | | | |
| | | solution) | | | | |
| 48 | | Pluronic P84 | 30.0 | | | 300.0 |
| | | (1% aqueous | | | | |
| | | solution) | | | | |
| 49 | 0.75 | | | | | 20.1 |
| 50 | 0.75 | | | pTSA | 0.52 | 30.4 |
| 51 | 0.75 | | | Acetic Acid | 3.5 | 23.5 |
| 52 | | Pluronic P84 | 78.0 | | | 780.0 |
| | | (1% aqueous | | | | |
| | | solution) | | | | |
| 53 | | Pluronic P84 | 15.0 | | | 150.0 |
| | | (1% aqueous | | | | |
| | | solution) | | | | |
| 54 | | Pluronic P84 | 15.0 | | | 150.0 |
| | | (1% aqueous | | | | |
| | | solution) | | | | |
| 55 | | Pluronic P84 | 15.0 | | | 150.0 |
| | | (1% aqueous | | | | |
| | | solution) | | | | |
| 56 | | Pluronic P84 | 15.0 | | | 150.0 |
| | | (1% aqueous | | | | |
| | | solution) | | | | |
| 57 | | Pluronic P84 | 15.0 | | | 150.0 |
| | | (1% aqueous | | | | |
| | | solution) | | | | |
| 58 | 0.73 | Pluronic P84 | 2.0 | | | 20.0 |
| | | (1% aqueous | | | | |
| | | solution) | | | | |
| 59 | 0.81 | Pluronic P84 | 2.0 | | | 20.0 |
| | | (1% aqueous | | | | |
| | | solution) | | | | |
| 60 | 0.88 | Pluronic P84 | 2.0 | | | 20.0 |
| | | (1% aqueous | | | | |
| | | solution) | | | | |
| 61 | | Pluronic P84 | 85.0 | | | 850.0 |
| | | (1% aqueous | | | | |
| | | solution) | | | | |
| 62 | | Pluronic P84 | 18.0 | | | 1800.0 |
| | | (10% aqueous | | | | |
| | | solution) | | | | |

### Post-Fixing Rinse Procedure

Some processes employed the use of a special rinse solution called a post-fix rinse (PFR). This special process was utilized with either fixing process described above. In all cases, after the standard DI water rinse step of the fixing process (as described in both fixing procedures above), approximately 70 milliliters of PFR was slowly poured manually onto the wafer to form a puddle reaching the wafer edge. The puddle was allowed to stay on the wafer for 60 seconds and then spun off. Wafers were then subjected to another DI water rinse process identical to the earlier DI water rinse. All subsequent process steps were carried out according to the particular example.

TABLE 4
Post-Fixer Rinse Formulation Examples

| Post-Fix Rinse | | | | | | | Total |
|---|---|---|---|---|---|---|---|
| Formulation | | | | | | | Quantity, |
| ID | Additive | Quantity, g | Solvent 1 | Quantity, g | Surfactant | Quantity, g | g. |
| A | Triflic Acid | 5.0 | DI Water | 445.0 | Pluronic | 50.0 | 500.0 |
| | | | | | P84 (1% | | |
| | | | | | aqueous | | |
| | | | | | solution) | | |
| B | Triflic Acid | 2.25 | DI Water | 200.3 | Pluronic | 22.5 | 225.0 |
| | | | | | P84 (1% | | |
| | | | | | aqueous | | |
| | | | | | solution) | | |
| C | Camphorsulfonic | 1.0 | DI Water | 89.0 | Pluronic | 10.0 | 100.0 |
| | Acid | | | | P84 (1% | | |
| | | | | | aqueous | | |
| | | | | | solution) | | |
| D | None | None | DI Water | 90.0 | Pluronic | 10.0 | 100.0 |
| | | | | | P84 (1% | | |
| | | | | | aqueous | | |
| | | | | | solution) | | |
| E | Triflic Acid | 2.8 | DI Water | 249.2 | Pluronic | 28.0 | 280.0 |
| | | | | | P84 (1% | | |
| | | | | | aqueous | | |
| | | | | | solution) | | |

### General Lithographic Procedure 3

### Double Patterning Lithographic Procedure—(Screening Mode)

Some of the effects and results of the double patterning procedure e.g. linewidth change of the lines prepared from the initial imaging step can be assessed using a Double Patterning Lithographic Procedure in a screening mode. In this mode the second exposure employs a blanket exposure so that the second imaging layer is removed by the developer and effects on the original lines can be assessed.

TIS193IL-PH (B50) photoresist was applied by spin-coating onto wafers containing fixed image patterns and was post-apply baked (PAB) for 90 seconds at 135° C. resulting in a resist film thickness of 130 nm. The wafers were then flood exposed through an open frame (without a photomask) on an ASML PAS 5500/1100 using annular illumination (0.85 σₒ/0.55 σᵢ). Wafers were subjected to a post-exposure bake (PEB) at 100° C. for 90 seconds, and IL patterns were developed via a puddle process for 60 seconds with OPD-262. A 30 seconds deionized (DI) water rinse and spin-dry step followed development.

### General Lithographic Procedure 4

### Double Patterning Lithographic Procedure

TIS193IL-PH (B50) photoresist was applied by spin-coating onto wafers containing fixed image patterns the and was post-apply baked (PAB) for 90 seconds at 135° C. resulting in a resist film thickness of 130 nm. The wafers were then exposed through the same photomask used in the general lithographic procedure. However, for this second imaging step, the photomask was mechanically shifted by the ASML PAS 5500/1100 scanner an appropriate distance to form new lines which are interdigitated with the original fixed lines resulting in double patterning.

For the purposes of this procedure, the CD of the original target feature formed during the general lithographic procedure (first patterning step) was 80 nm lines and 800 nm spaces. The photomask contains test lines that are patterned lengthwise in the y-direction and widthwise in the x-direction. For the second patterning, the reticle is shifted only in the x-direction so that the second pattern of lines (80 nm lines separated by 800 nm space) will be printed parallel to the fixed pattern. In order to form an 80 nm space or a 360 nm space between the original fixed lines of the first imaging step and the newly formed lines of the second imaging step, the photomask was shifted from its original x-position either 160 nm or 440 nm, respectively, for the second patterning step. With a 160 nm x-shift, the resulting nominal double pattern will be a repeating set of line and spaces consisting of the following repeat unit: 80 nm fixed line/80 nm space/80 nm second patterned line/560 nm space. Thus, an 80 nm second patterned line is printed within 80 nm proximity of an 80 nm fixed line. With a 440 nm x-shift, the resulting nominal double pattern will be a repeating set of line and spaces consisting of the following repeat unit: 80 nm fixed line/320 nm space/80 nm second patterned line/320 nm space. In this way, the 80 nm fixed and second patterned lines are equally spaced by 320 nm.

Wafers were exposed on an ASML PAS 5500/1100 annular illumination (0.85 σₒ/0.55 σᵢ). Wafers were subjected to a post-exposure bake (PEB) at 100° C. for 90 seconds, and IL patterns were developed via a puddle process for 60 seconds with OPD-262. A 30 seconds deionized (DI) water rinse and spin-dry step followed development.

### Lithographic Process Examples 2-17

The following conditions apply to Lithographic Process Examples 2-17:
Initial imaging: General Lithographic Procedure 2
Fixer formulation ID: Fixer Formulation 62
Fixer process: puddle fix process with a 30 second DI water rinse before bake
Double patterning lithographic procedure: General Lithographic Procedure 4
CD data based on top-down CD SEM measurements using one wafer per example and measuring 15 points per wafer on the original photoresist lines.

TABLE 5

| | | | | CD Growth | CD Growth from |
|---|---|---|---|---|---|
| | Post Fix | Post Fix | | from Fix | Double Patterning |
| Lithographic | Bake | bake | Additional | Process, (fix | Process (DP |
| Process | Temperature, | Time | Processing | CD - litho cd | process CD - litho |
| Example # | ° C. | (seconds) | Notes | in nm) | CD in nm) |
| 2 | 165 | 90 | 160 nm | 7.4 | 14.6 |
| | | | reticle shift | | |
| 3 | 165 | 90 | 440 nm | | −14.6 |
| | | | reticle shift | | |
| 4 | 175 | 90 | 160 nm | 5.7 | 12.9 |
| | | | reticle shift | | |
| 5 | 175 | 90 | 440 nm | | −28.2 |
| | | | reticle shift | | |
| 6 | 185 | 90 | 160 nm | 4.9 | −12 |
| | | | reticle shift | | |
| 7 | 185 | 90 | 440 nm | | −31.4 |
| | | | reticle shift | | |
| 8 | 195 | 90 | 160 nm | 3.6 | −21.4 |
| | | | reticle shift | | |
| 9 | 195 | 90 | 440 nm | | −40.2 |
| | | | reticle shift | | |
| 10 | 200 | 30 | 160 nm | 4.3 | −1.7 |
| | | | reticle shift | | |
| 11 | 200 | 30 | 440 nm | | −29.9 |
| | | | reticle shift | | |
| 12 | 200 | 90 | 160 nm | 4.4 | −20 |
| | | | reticle shift | | |
| 13 | 200 | 90 | 440 nm | | −32.2 |
| | | | reticle shift | | |
| 14 | 200 | 150 | 160 nm | 5.5 | −8.8 |
| | | | reticle shift | | |
| 15 | 200 | 150 | 440 nm | | −32 |
| | | | reticle shift | | |
| 16 | 205 | 90 | 160 nm | 5.8 | −7.5 |
| | | | reticle shift | | |
| 17 | 205 | 90 | 440 nm | | −37.6 |
| | | | reticle shift | | |

In Lithographic Examples 2-17, photoresist lines from both lithographic imaging steps were successfully produced after Lithographic Procedure 4. The experiments also indicate that the time and temperature of the fixing process are key parameters in controlling CD changes of the first patterned images, giving flexibility to the imaging process.

### Lithographic Process Examples 18-38

### Lithographic Process to Screen Fixing Results

The following conditions apply to Lithographic Process Examples 18-38:
Initial imaging: General Lithographic Procedure 1
Fixing procedure bake temperature was 130° C. for 90 seconds.
Determination of whether patterns were successfully fixed was made by cross-sectional SEM evaluation of wafers after application of the fixing procedure and an additional process of dipping the wafer into a PGMEA bath for 60 seconds and blowing the surface dry with compressed air. Fixing quality was determined by visual inspection of either cross-sectional or CD SEM images. If the line space pattern fidelity was intact after both the fixing process and the double patterning lithographic process, imaged patterns were said to be fixed (Y). Partially fixed patterns were examples in which line fidelity was significantly perturbed by either the fixing process or the double patterning lithographic process. In such cases lines took on a smeared or melted appearance or the expected pattern was no longer discernable, but some resist film remained. If the imaged pattern was completely dissolved or dissolved to the point that only film residue remained, patterns were described as “not fixed” (N).

TABLE 6

| | | | Rinse/ | | |
|---|---|---|---|---|---|
| | | Fixing | Bake | | Were |
| Lithographic | Fixer | Process | Sequence | Rinse | Patterns |
| Process | For- | (PP | (RBB or | Time | Successfully |
| Example # | mulation | or SCP) | BBR) | (seconds) | Fixed? (y/n) |
| 18 | 2 | SCP | BBR | 15 | y |
| 19 | 3 | SCP | none | | y |
| 20 | 4 | SCP | none | | y |
| 21 | 5 | SCP | none | | y |
| 22 | 5 | SCP | BBR | 15 | y |
| 23 | 6 | SCP | none | | y |
| 24 | 7 | SCP | BBR | 15 | n |
| 25 | 8 | SCP | BBR | 15 | y |
| 26 | 9 | SCP | BBR | 15 | y |
| 27 | 10 | SCP | BBR | 15 | y |
| 28 | 11 | SCP | BBR | 15 | y |
| 29 | 12 | SCP | BBR | 15 | y |
| 30 | 13 | SCP | BBR | 15 | y |
| 31 | 14 | SCP | BBR | 15 | n |
| 32 | 15 | SCP | BBR | 15 | n |
| 33 | 16 | SCP | BBR | 15 | n |
| 34 | 17 | SCP | BBR | 15 | y |
| 35 | 18 | SCP | BBR | 15 | y |
| 36 | 19 | PP | BBR | 15 | partial |
| 37 | 20 | PP | BBR | 15 | y |
| 38 | 21 | PP | BBR | 15 | y |

Both fixing processes were generally suitable for fixing the images as were the two rinse/bake sequences.

### Lithographic Process Examples 39-50

### Double Patterning Lithographic Procedure—(Screening Mode)

The following conditions apply to Lithographic Process Examples 38-49:
Initial imaging: General Lithographic Procedure 2
Fixer process: puddle fix process with a 15 second DI water rinse occurring after the bake step
Double patterning lithographic procedure: General Lithographic Procedure 3
CD data based on top-down CD SEM measurements using two wafers per example and measuring 119 points per wafer

TABLE 7

| | | | | Did | | CD Growth from |
|---|---|---|---|---|---|---|
| | | Post Fix | Post Fix | Pattern | CD Growth from | Double Patterning |
| Lithographic | | Bake | bake | Successfully | Fix Process, (fix | Process (DP |
| Process | Fixer | Temperature, | Time | Fix | CD - litho cd in | process CD - litho |
| Example # | Formulation | ° C. | (seconds) | (y/n) | nm) | CD in nm) |
| 39 | 22 | 100 | 90 | y | 7.9 | 34.3 |
| 40 | 22 | 115 | 90 | y | 7.6 | 33.7 |
| 41 | 22 | 130 | 90 | y | 7.8 | 31.1 |
| 42 | 23 | 100 | 90 | y | 7.9 | 42.1 |
| 43 | 23 | 115 | 90 | y | 7.9 | 42.3 |
| 44 | 23 | 130 | 90 | y | 8.5 | 41.6 |
| 45 | 24 | 100 | 90 | y | 7.4 | 38.7 |
| 46 | 24 | 115 | 90 | y | 7.6 | 39.4 |
| 47 | 24 | 130 | 90 | y | 8.2 | 39.6 |
| 48 | 25 | 100 | 90 | y | 7.3 | 34.5 |
| 49 | 25 | 115 | 90 | y | 7.5 | 30.9 |
| 50 | 25 | 130 | 90 | y | 8.8 | 24.4 |

Within the parameters of the experiment (1% to 4% by weight Hexamethylenediamine and fixer bake temperature of 100° C. to 130° C. for 90 seconds), all process examples in this set showed good fixing. CD linewidth growth was modest in the fixing process and significant in the second patterning step.

### Lithographic Process Examples 51-90

The following conditions apply to Lithographic Process Examples 51-90:
Initial imaging: General Lithographic Procedure 2
Fixer process: puddle fix process
Double patterning lithographic procedure: General Lithographic Procedure
CD data based on top-down CD SEM measurements using one wafer per example and measuring 15 points per wafer

TABLE 8

| | | Post Fix | Post Fix | Rinse/Bake | DI Water | Did Pattern | CD Growth from | |
|---|---|---|---|---|---|---|---|---|
| Lithographic | | Bake | bake | Sequence | Rinse | Successfully | Fix Process, (fix | CD Growth from Double |
| Process | Fixer | Temperature, | Time | (RBB | Time | Fix | CD - litho cd in | Pattering Process (DP process |
| Example # | Formulation | ° C. | (seconds) | or BBR) | (seconds) | (y/n) | nm) | CD - litho CD in nm) |
| 51 | 22 | 130 | 90 | BBR | 15 | y | 8.23 | 37.32 |
| 52 | 22 | 130 | 90 | RBB | 15 | n | 7.59 | no lines |
| 53 | 22 | 180 | 90 | BBR | 15 | y | 9.01 | 32.71 |
| 54 | 26 | 180 | 90 | BBR | 15 | y | 9.63 | 33.27 |
| 55 | 25 | 100 | 90 | BBR | 15 | y | 7.79 | 25.87 |
| 56 | 25 | 100 | 90 | BBR | 90 | y | 9.96 | no cd-some lines were present |
| 57 | 25 | 100 | 180 | BBR | 15 | y | 7.28 | 25.68 |
| 58 | 25 | 85 | 90 | BBR | 15 | y | 7.78 | 25.38 |
| 59 | 25 | 85 | 180 | BBR | 15 | y | 7.13 | 23.66 |
| 60 | 30 | 100 | 90 | BBR | 15 | partial | 7.89 | no lines |
| 61 | 30 | 100 | 180 | BBR | 15 | partial | 7.49 | no lines |
| 62 | 31 | 100 | 90 | BBR | 15 | partial | 11.88 | no lines |
| 63 | 31 | 100 | 180 | BBR | 15 | partial | 7.14 | no lines |
| 64 | 35 | 180 | 90 | BBR | 15 | y | 8.89 | 33.81 |
| 65 | 35 | 180 | 225 | BBR | 15 | y | 9.18 | 28.23 |
| 66 | 36 | 180 | 225 | BBR | 15 | y | 8.42 | 33.66 |
| 67 | 36 | 180 | 129 | BBR | 15 | y | 8.8 | 34.91 |
| 68 | 37 | 180 | 225 | BBR | 15 | y | 9.03 | 33.55 |
| 69 | 37 | 180 | 900 | BBR | 15 | partial | 9.86 | no lines |
| 70 | 38 | 180 | 225 | BBR | 15 | y | 27.78 | 34.3 |
| 71 | 38 | 180 | 900 | BBR | 15 | partial | no lines | no lines |
| 72 | 42 | 130 | 90 | BBR | 30 | y | 9.8 | 32.7 |
| 73 | 42 | 165 | 90 | BBR | 30 | y | 10 | 30.13 |
| 74 | 42 | 200 | 90 | BBR | 30 | y | 8.5 | 17.54 |
| 75 | 42 | 200 | 180 | BBR | 30 | y | 7.19 | 14.38 |
| 76 | 42 | 235 | 90 | BBR | 30 | y | 3.37 | 7.44 |
| 77 | 42 | 235 | 180 | BBR | 30 | y | 3.96 | 6.71 |
| 78 | 47 | 110 | 90 | BBR | 30 | partial | 4.1 | no CD data-lines smeared |
| 79 | 47 | 165 | 90 | BBR | 30 | y | 4.58 | 16.43 |
| 80 | 47 | 110 | 90 | BBR | 30 | y | no cd data | 15.1 |
| | | 165 | 90 | | | | | |
| | | double | | | | | | |
| | | bake | | | | | | |
| 81 | 47 | 135 | 90 | BBR | 30 | partial | 4.9 | no CD data |
| 82 | 47 | 135 | 90 | BBR | 30 | y | 5.6 | 12.2 |
| | | 165 | 90 | | | | | |
| | | double | | | | | | |
| | | bake | | | | | | |
| 83 | 48 | 165 | 90 | BBR | 30 | y | 5.3 | 15.9 |
| 84 | 53 | 165 | 90 | RBB | 30 | y | 3.8 | 23.91 |
| 85 | 54 | 165 | 90 | RBB | 30 | y | −6.7 | 7.56 |
| 86 | 55 | 165 | 90 | RBB | 30 | partial | no cd data | no CD data |
| 87 | 56 | 165 | 90 | RBB | 30 | partial | no cd data | no CD data |
| 88 | 57 | 165 | 90 | RBB | 30 | partial | −15.92 | −5.41 |
| 89 | 61 | 165 | 90 | RBB | 30 | y | 3.7 | 26.1 |
| 90 | 61 | 200 | 90 | RBB | 30 | y | 1.9 | 9.1 |

Lithographic Process Examples 51-90 indicate that concentration and size of the fixing agent can be used to adjust line width changes. An effective concentration of the fixing agent, which can vary depending on the fixing agent is required. Temperature of the post fix bake can also be used to adjust the linewidth changes. A double post fix bake process can be employed, as can a process employing a rinse before or a rinse after the post fix bake. Use of a cosolvent in the in fixer must be carefully selected and the concentration controlled to prevent dissolution of the image.

### Lithographic Process Examples 91-94

### Lithographic Process to Screen Fixing Results

The following conditions apply to Lithographic Process Examples 91-94:
Initial imaging: General Lithographic Procedure 2
Fixer process: spin coat fix process with a 15 second DI water rinse occurring after the bake step
Determination of whether patterns were successfully fixed was made by top-down CD SEM evaluation of wafers after application of the fixing procedure and an additional process of dipping the wafer into a PGMEA bath for 60 seconds and blowing the surface dry with compressed air. Fixing quality was evaluated as described in Lithographic Process Examples 17-37.

TABLE 9

| | | | | Did | |
|---|---|---|---|---|---|
| | | Post Fix | | Pattern | |
| Lithographic | | Bake | Post Fix | Successfully | CD Growth from Fix |
| Process | Fixer | Temperature, | bake Time | Fix | Process, (fix CD - |
| Example # | Formulation | ° C. | (seconds) | (y/n) | litho cd in nm) |
| 91 | 43 | 90 | 90 | y | 13.5 |
| | | 165 | 90 | | |
| | | double bake | | | |
| 92 | 44 | 90 | 90 | partial | 13 |
| | | 165 | 90 | | |
| | | double bake | | | |
| 93 | 45 | 90 | 90 | y | 19.4 |
| | | 165 | 90 | | |
| | | double bake | | | |
| 94 | 46 | 90 | 90 | partial | 22.3 |
| | | 165 | 90 | | |
| | | double bake | | | |

### Lithographic Process Examples 95-99

### Double Patterning Lithographic Procedure—(Screening Mode)

The following conditions apply to Lithographic Process Examples 95-99
Initial imaging: General Lithographic Procedure 2
Fixer process: spin coat fix process with a 15 or 30 seconds DI water rinse step applied after the bake step
Double patterning lithographic procedure: General Lithographic Procedure 3
CD data based on top-down CD SEM measurements using one wafer per example and measuring 15 points per wafer

TABLE 10

| | | | | | | | CD Growth |
|---|---|---|---|---|---|---|---|
| | | | | | | | from Double |
| | | | | | | CD Growth | Patterning |
| | | | | | | from Fix | Process |
| | | Post Fix | Post Fix | DI Water | | Process, | (DP |
| Lithographic | | Bake | bake | Rinse | Did Pattern | (fix CD - | process |
| Process | Fixer | Temp., | Time | Time | Successfully | litho cd in | CD - litho |
| Example | Formulation | ° C. | (seconds) | (seconds) | Fix (y/n) | nm) | CD in nm) |
| 95 | 49 | 165 | 90 | 30 | y | 8.99 | 37.19 |
| 96 | 58 | 135 | 90 | 30 | y | 8.43 | 33.88 |
| 97 | 58 | 165 | 90 | 30 | y | 9.61 | 30.19 |
| 98 | 59 | 165 | 90 | 30 | y | 10.97 | 24.55 |
| 99 | 60 | 165 | 90 | 30 | y | 11.39 | 34.06 |

Lithographic Process Examples 95-99 demonstrate fixing capability of the spin coat fixer process using fixer formulations containing a range of Ethylenediamine concentrations from 0.5% to 1.7% by weight.

### Lithographic Process Examples 100-108

### Double Patterning Lithographic Procedure—(Screening Mode)

The following conditions apply to Lithographic Process Examples 100-108:
Initial imaging: General Lithographic Procedure 2
All subjected to a post-fix rinse process
Double patterning lithographic procedure: General Lithographic Procedure 3
CD data based on top-down CD SEM measurements using one wafer per example and measuring 15 points per wafer.

TABLE 12

| | | | | | | | | | CD Growth | CD Growth from |
|---|---|---|---|---|---|---|---|---|---|---|
| | | Post- | Fixing | Post Fix | | Rinse/Bake | DI Water | | from Fix | Double Patterning |
| | | Fixer | Process | Bake | Post Fix | Sequence | Rinse | Did Pattern | Process, (fix | Process (DP |
| Process | Fixer | Rinse | (PP or | Temperature, | bake Time | (RBB or | Time | Successfully | CD - litho | process CD - litho |
| Example # | Formulation | Formulation | SCP) | ° C. | (seconds) | BBR) | (seconds) | Fix (y/n) | cd in nm) | CD in nm) |
| 100 | 61 | A | PP | 165 | 90 | RBB | 30 | y | no CD data | 17.7 |
| 101 | 48 | B | PP | 165 | 90 | BBR | 30 | y | no CD data | 7.7 |
| 102 | 48 | B | PP | 165 | 90 | BBR | 30 | y | 3.4 | 1.2 |
| 103 | 58 | E | SCP | 135 | 90 | BBR | 30 | y | no CD data | 21.2 |
| 104 | 58 | E | SCP | 165 | 90 | BBR | 30 | y | no CD data | 17.0 |
| 105 | 59 | E | SCP | 165 | 90 | BBR | 30 | y | no CD data | 21.1 |
| 106 | 60 | E | SCP | 165 | 90 | BBR | 30 | y | no CD data | 25.9 |
| 107 | 22 | C | PP | 100 | 90 | BBR | 15 | y | 7.7 | 42.3 |
| 108 | 25 | D | PP | 100 | 90 | BBR | 15 | y | 8.2 | 26.0 |

Lithographic examples 100-108 show the possibility of using a variety of post fixer rinse formulations applied within either the SCP or PP fixing process. Examples 101 and 102 were relatively effective processes with regard to limiting total CD growth.

### Lithographic Process Examples 109-111

### Double Patterning Lithographic Procedure—(Screening Mode)

The following conditions apply to Lithographic Process Examples 109-111
Initial imaging: General Lithographic Procedure 2
Fixer formulation: Fixer Formulation 52
Fixer process: puddle fix process with a 30 seconds DI water rinse applied before the bake step which is 165° C. for 90 seconds.
Double patterning lithographic procedure: General Lithographic Procedure 3
CD data based on top-down CD SEM measurements using one wafer per example and measuring 15 points per wafer

TABLE 13

| | | | CD Growth | CD Growth from |
|---|---|---|---|---|
| | Fixer | | from Fix | Double Patterning |
| | Puddle | Did Pattern | Process, | Process (DP |
| Process | Time, | Successfully | (fix CD - litho | process CD - |
| Example # | seconds | Fix (y/n) | cd in nm) | litho CD in nm) |
| 109 | 60 | Y | 3.77 | 20.6 |
| 110 | 120 | Y | 2.6 | 24.8 |
| 111 | 180 | Y | 3.5 | 27.2 |

Lithographic Process Examples 109-111 demonstrated that a shorter fixer puddle time leads to a reduction of total CD growth in the double patterning process.

### Lithographic Process Example 112

In this example, double patterning is demonstrated using a bottom anti-reflective coating (ARC) in combination with a non-silicon containing resist. The first image is patterned using General Lithographic Procedure 2 with the following exceptions. In the first exception, the UL is replaced with a BARC (ARC29A; supplied by Brewer Science, Inc.) and is coated to a 90 nm film thickness. In the second exception, a resist comprising a non-silicon containing polymer with incorporated anhydride functionality as described in U.S. Pat. No. 5,843,624, is used as a substitute for the imaging layer. The resulting image is fixed using the puddle process (PP) employing Fixer Formulation 62. The fixing procedure also uses a 30 second rinse-before-bake (RBB) process and a 175° C. post-fix bake temperature with duration of 90 seconds and. The resulting stack is then subjected to the General Lithographic Procedure 4 in which a resist comprising a non-silicon containing polymer with incorporated anhydride functionality as described in U.S. Pat. No. 5,843,624, is used as a substitute for the imaging layer. Photoresist lines from both imaging steps are successfully printed.

### Lithographic Process Example 113

In this example, an extra step is inserted into the fixing/double patterning process. An underlayer film is used to encapsulate the fixed image before applying the double patterning procedure. The underlayer formulation used in the first patterning step is modified to contain a 10-fold increase in thermal acid generator and then coated on the fixed images.

Thus, the first image is patterned using General Lithographic Procedure 2. The resulting image is fixed using the puddle process (PP) employing Fixer Formulation 61. The fixing procedure also uses a 30 second rinse-before-bake (RBB) process and a 175° C. post-fix bake temperature with duration of 90 seconds and. The fixed image is then spin-coated with the underlayer having the higher concentration of thermal acid generator described above. The UL film is baked for 90 seconds at 200° C. to yield a nominal UL film thickness of 160 nm and to encapsulate the fixed images. The resulting stack is then subjected to the General Lithographic Procedure 4. Photoresist lines from the imaging step are successfully printed on the second UL.

To achieve a final double patterned image, the wafer comprising the stack from above is then subjected to a vertical dry etch process to etch away UL that is not masked by any IL patterns. The IL, containing Si, is a good etch mask to protect any underlying underlayer to result in high fidelity double patterned images.

### Lithographic Process Example 114

Lithographic Process 112 was repeated with the exception that the first coated photoresist comprises a non-silicon containing copolymer of 60% hydroxystyrene and 40% t-butyl acrylate and the fixer formulation comprises a 5% solution of a 20% glycidyl acrylate-80% methylacrylate copolymer in a 30% decane/70% octanol solvent system. Photoresist lines from both imaging steps are successfully printed.

While the invention has been described herein with reference to the specific embodiments thereof, it will be appreciated that changes, modifications and variations can be made without departing from the spirit and scope of the inventive concept disclosed herein. Accordingly, it is intended to embrace all such changes, modification and variations that fall with the spirit and scope of the appended claims.

What is claimed is:

1. A process for manufacturing a semiconductor device using a multiple exposure patterning process, comprising:
a) providing a coated semiconductor substrate with an antireflective coating or an underlayer,
b) applying in a first coating step, a first photosensitive composition over the coated semiconductor substrate to produce a bilayer stack,
c) exposing the first photosensitive composition in the bilayer stack in a imagewise manner to actinic radiation in a first exposure step to produce a first pattern,
d) developing the exposed first photosensitive composition in an aqueous base developer to produce an imaged bilayer stack containing a relief image,
e) rinsing the imaged bilayer stack containing the relief image with an aqueous liquid optionally containing a surfactant,
f) applying a fixer solution to the imaged bilayer stack to stabilize (fix) the relief image,
g) applying an optional bake step,
h) rinsing the imaged bilayer stack containing the stabilized image with a liquid optionally containing a surfactant,
i) applying a second optional bake step,
j) applying in a second coating step a second photosensitive composition onto the imaged bilayer stack to produce a multilayer stack,
k) exposing the second photosensitive composition in the multilayer stack in an imagewise manner to actinic radiation in a second exposure step to produce a second pattern in which the second pattern is offset from the first pattern by a predetermined amount,
l) developing the exposed second photosensitive composition in an aqueous base developer to produce an imaged multilayer stack containing a second relief image, and
m) rinsing the imaged multilayer stack containing the second relief image with an aqueous liquid optionally containing a surfactant;
wherein the first and second photosensitive compositions each comprise a photoacid generator and a substantially aqueous base insoluble polymer whose aqueous base solubility increases upon treatment with acid and further comprises an anchor group, and the fixer solution comprises a polyfunctional fixer compound which is reactive with the anchor group, but does not contain silicon and wherein the semiconductor substrate stays within a lithographic cell from at least the first coating step until at least after the final exposure.

2. The process of claim 1 wherein the first and second photosensitive compositions are the same.

3. The process of claim 1 wherein the first and second photosensitive compositions are different.

4. The process of claim 1 wherein the semiconductor substrate provided is coated with an antireflective coating.

5. The process of claim 1 wherein the anchor group is selected from the group consisting of carboxylic acids, sulfonic acid, phenols, hydroxyimides, hydroxymethylimides, silanols, thiophenols, and amino groups all of which may be protected with an acid sensitive protecting group and epoxides, isocyanates, and carboxylic acid anhydrides.

6. The process of claim 5 wherein the anchor group is selected from the group consisting of phenols, and acidic alcohols, all of which may be protected with an acid sensitive protecting group, epoxides, and carboxylic acid anhydrides.

7. The process of claim 1 wherein the fixer solution comprises water.

8. The process of claim 8 wherein the fixer solution further comprises a water miscible organic solvent.

9. The process of claim 8 wherein the water soluble organic solvent is selected from the group consisting of methanol, ethanol, 1-propanol, 2-propanol, 1-butanol, 2-butanol, propyleneglycol monomethyl ether (PGME), and ethyl lactate.

10. The process of claim 1 wherein the fixer solution is a nonpolar organic solvent.

11. The process of claim 10 wherein the nonpolar organic solvent is at least one C₅ to C₂₀ linear, branched or cyclic alkane.

12. The process of claim 10 wherein the nonpolar organic solvent is selected from the group consisting of hexane, cyclohexane, octane, decane and dodecane or mixtures thereof.

13. The process of claim 1 wherein the functional group in the polyfunctional fixer compound which is reactive with the anchor group is selected from the group consisting of a carboxylic acid, a sulfonic acid, a phenol, a hydroxyimide, a hydroxymethylimide, a silanol, a carboxylic acid anhydride, an epoxide, an isocyanate, a thiophenol, and an amino group.

14. The process of claim 13 wherein the functional group in the polyfunctional fixer compound which is reactive with the anchor group is an amino group.

15. The process of claim 1 wherein the fixer solution contains at least one surfactant.

16. The process of claim 15 wherein the surfactant is selected from the group consisting of a nonionic surfactant, an anionic surfactant, an amphoteric surfactant, and mixtures thereof.

17. The process of claim 1 wherein the fixer solution further comprises a polymer.

18. The process of claim 21 wherein the polymer is selected from the group consisting of polyethylene oxide, polypropylene oxide, and polyvinyl alcohol.

19. The process of claim 1 wherein the rinse solution comprises at least one photoresist casting solvent or edge bead remover solvent, or water, or mixtures thereof.

20. The process of claim 19 wherein the photoresist casting solvent or edge bead remover solvent is selected from the group consisting of propyleneglycol monomethyl ether (PGME), 2-heptanone, ethylene glycol monoethyl ether acetate (PGMEA), diethylene glycol dimethyl ether, and ethyl lactate.

21. The process of claim 26 wherein the rinse solution comprises water.

22. The process of claim 19 wherein the rinse solution further comprises an acid.

23. The process of claim 22 wherein the acid is a sulfonic or a carboxylic acid.

24. The process of claim 1 wherein the exposure wavelength is <250 nm.

25. The process of claim 1 wherein the exposure wavelength is <200 nm.

26. The process of claim 1 wherein a bake step is employed immediately before the rinse step.

27. The process of claim 1 wherein a bake step is employed immediately after the rinse step.

28. The process of claim 1 wherein the semiconductor substrate provided is coated with an underlayer and the substantially aqueous base insoluble polymer contains silicon.

29. The process of claim 28 wherein therein is a second underlayer.

30. The process of claim 1 wherein the fixer is polymeric.
